(19) United States
(12) Patent Application Publication
(10) Pub. No.: US 2016/0163949 A1
(43) Pub. Date: Jun. 9, 2016

(54) FLEXIBLE THERMOELECTRIC GENERATOR

(71) Applicant: Thermogen Technologies, Inc., Corvallis, OR (US)

(72) Inventors: Ingo STARK, Corvallis, OR (US); Marcus S. WARD, Salem, OR (US)

(73) Assignee: Perpetua Power Source Technologies

(21) Appl. No.: 14/559,916

(22) Filed: Dec. 3, 2014

(51) Int. Cl. H01L 35/32; H01L 35/34; H01L 35/08

(52) U.S. Cl. CPC H01L 35/32; H01L 35/08; H01L 35/34

(57) ABSTRACT

A flexible thermoelectric generator may include a substrate formed of an electrically insulating material, and may have a series of thermoelectric legs formed of alternating dissimilar materials arranged in at least two rows on the substrate. Each one of the thermoelectric legs may define a leg axis extending along a lengthwise direction of the thermoelectric leg. The axes may be generally parallel to a substrate surface and non-parallel to a row axis. The substrate may include at least one substrate flex zone located between two of the rows of thermoelectric legs. The substrate flex zone may define a relatively rigid first thermopile cluster and a relatively rigid second thermopile cluster. The substrate may have greater flexibility in the substrate flex zone relative to the flexibility of the substrate in the first thermopile cluster and the second thermopile cluster.

### FIELD

The present disclosure relates generally to thermoelectric devices and, more particularly, to a flexible thermoelectric generator that can be bent around a curved surface and/or flex in one or more directions.

### BACKGROUND

Thermoelectric generators are self-sufficient energy sources that convert thermal energy into electrical energy under the Seebeck effect—a phenomenon whereby temperature gradient is converted into electricity due to charge carrier diffusion in a conductor. Electrical power may be generated under the Seebeck effect by utilizing thermocouples. Each thermocouple may be comprised of a pair of thermoelectric legs joined at one end. The pair of thermoelectric legs may be formed of dissimilar materials including n-type and p-type thermoelectric material. The terms n-type and p-type respectively refer to the negative and positive types of charge carriers within the thermoelectric material.

Electricity is generated due to the temperature gradient between the ends of the thermocouple. The temperature gradient may be artificially applied or it may be natural-occurring such as the waste heat that is constantly rejected by the human body. For example, a wrist watch may be exposed to air at ambient temperature wherein the air acts as a heat sink on one side of the wrist watch. An opposite side of the wrist watch may be exposed to the higher temperature of the wearer's skin which acts as a heat source. The temperature gradient across the thickness of the wristwatch may be exploited by a thermoelectric generator which may generate a supply of power sufficient to operate the wrist watch as a self-contained unit.

Often with waste heat sources, only a small temperature difference exists between the heat source and the heat sink. Because of the small temperature difference, a relatively large number of thermocouples must be connected in series in order to generate a sufficiently large thermoelectric voltage for powering an electronic device. The relatively large number of thermocouples may occupy a relatively large surface area which must be thermally coupled between the heat source and heat sink. In addition, in order for the thermoelectric generator to generate maximum power, heat flow across the thermocouples must be optimized.

Conventional thermoelectric generators are rigid, non-flexible devices having flat surfaces which may present challenges in implementing such devices for use on curved surfaces. For example, the inability of a flat thermoelectric generator to conform to the curvature of a wearer's skin such as a wrist, an arm, or other body part may present challenges in powering a wearable electronic device. The flatness of conventional thermoelectric generators may result in sub-optimal heat flow across the thermocouples which may limit the power-generating capability of the device. The rigidity of conventional thermoelectric generators may limit the ability of such devices to flex and maintain contact with the wearer's skin during normal body movements which may have a detrimental affect on thermoelectric performance and on the comfort of the wearer.

As can be seen, there exists a need in the art for a thermoelectric generator which can be bent around curved surfaces and which can flex in order to provide improved thermoelectric performance and comfort. Ideally, such a thermoelectric generator has minimal weight and occupies a minimal amount of space.

### SUMMARY

The above-described needs associated with thermoelectric generators are specifically addressed and alleviated by the embodiments disclosed herein wherein a flexible thermoelectric generator may include a substrate formed of an electrically insulating material. The flexible thermoelectric generator may have a series of thermoelectric legs formed of alternating dissimilar materials arranged in at least two rows on the substrate. Each one of the thermoelectric legs may define a leg axis extending along a lengthwise direction of the thermoelectric leg. The axes may be generally parallel to a substrate surface and non-parallel to a row axis. The substrate may include at least one substrate flex zone located between two of the rows of thermoelectric legs. The substrate flex zone may define a relatively rigid first thermopile cluster and a relatively rigid second thermopile cluster. The substrate may have greater flexibility in the substrate flex zone relative to the flexibility of the substrate in the first thermopile cluster and the second thermopile cluster.

Also disclosed is a thermoelectric generator system which may include a flexible band element, and a flexible thermoelectric generator mounted to the flexible band element. The flexible thermoelectric generator may include a substrate formed of an electrically insulating material. The flexible thermoelectric generator may have a series of thermoelectric legs formed of alternating dissimilar materials arranged in at least two rows on the substrate. Each one of the thermoelectric legs may define a leg axis extending along a lengthwise direction of the thermoelectric leg. The axes may be generally parallel to a substrate surface and non-parallel to a row axis. The substrate may include at least one substrate flex zone located between two of the rows of thermoelectric legs. The substrate flex zone may define a relatively rigid first thermopile cluster and a relatively rigid second thermopile cluster. The substrate may have greater flexibility in the substrate flex zone relative to the flexibility of the substrate in the first thermopile cluster and the second thermopile cluster.

In a further embodiment, disclosed is a method of forming a thermoelectric generator system. The method may include providing a substrate having a substrate surface and formed of an electrically insulating material having a relatively low thermal conductivity. The method may additionally include forming in the substrate at least one substrate flex zone along which the substrate can bend in an out-of-plane direction. The method may also include forming at least one row of thermoelectric legs on each side of the substrate flex zone. The substrate flex zone may separate a relatively rigid first thermopile cluster from a relatively rigid second thermopile cluster. Each thermopile cluster may include at least one row of the thermoelectric legs formed of alternating dissimilar materials and electrically connected in series. The substrate may have greater flexibility in the substrate flex zone relative to the flexibility of the substrate in the first thermopile cluster and the second thermopile cluster. Each one of the thermoelectric legs may define a leg axis extending along a lengthwise direction of the thermoelectric leg. The leg axis may be generally parallel to the substrate surface and non-parallel to a row axis.

The features, functions and advantages that have been discussed can be achieved independently in various embodiments of the present disclosure or may be combined in yet other embodiments, further details of which can be seen with reference to the following description and drawings below.

### BRIEF DESCRIPTION OF THE DRAWINGS

These and other features of the present disclosure will become more apparent upon reference to the drawings wherein like numbers refer to like parts throughout and wherein:

FIG. 1 is a top view of a thermoelectric generator having a series of thermoelectric legs, and further illustrating a substrate having at least one substrate flex zone;

FIG. 2 is a sectional view of the thermoelectric generator of FIG. 1;

FIG. 3 is a perspective view of a thermoelectric generator system configured as a flexible bi-stable spring band;

FIG. 4 is a partially cutaway perspective view of the thermoelectric generator system illustrating the substrate being bent along the substrate flex zone;

FIG. 5 is a top view of the thermoelectric generator integrated into the bi-stable spring band of FIG. 4;

FIG. 6 is a sectional view of the thermoelectric generator system and illustrating the thermoelectric generator sandwiched between an outer band and the bi-stable spring band;

FIG. 7 is a sectional view of the bi-stable spring band and illustrating the substrate bent along the substrate flex zone to accommodate the concave curvature of the bi-stable spring band;

FIG. 8 is a perspective view of the flexible bi-stable spring band in a curved state wrapped around a wrist of a wearer;

FIG. 9 is a sectional view of the thermoelectric generator system and illustrating the substrate bent along multiple substrate flex zones;

FIG. 10 is a sectional view of the thermoelectric generator system and illustrating the substrate bent along a substrate flex zone to accommodate a convex curvature of the bi-stable spring band along a transverse direction thereof;

FIG. 11 is a perspective view of the thermoelectric generator system integrated into a flexible adhesive patch;

FIG. 12 is a top view of an embodiment of a thermoelectric generator having a single flex zone allowing for flexing of the substrate in a single direction;

FIG. 13 is a top view of an embodiment of a thermoelectric generator having multiple, parallel substrate flex zones;

FIG. 14 is a sectional view of a thermoelectric generator and illustrating single thermally conductive strips aligned with opposite leg ends of the thermoelectric legs;

FIG. 15 is a top view of an embodiment of a thermoelectric generator wherein the thermoelectric legs form a zig-zag pattern;

FIG. 16 is a sectional view of a thermoelectric generator and illustrating an electrically insulating layer interposed between the thermoelectric legs;

FIG. 17 is a top view of a flexible thermoelectric generator system having a plurality of thermopile clusters electrically connected in series and coupled to power management electronics;

FIG. 18 is a top view of a plurality of thermopile clusters electrically connected in parallel and coupled to power management electronics; and

FIG. 19 is a flow diagram illustrating an embodiment of a method of forming a thermoelectric generator system.

### DETAILED DESCRIPTION

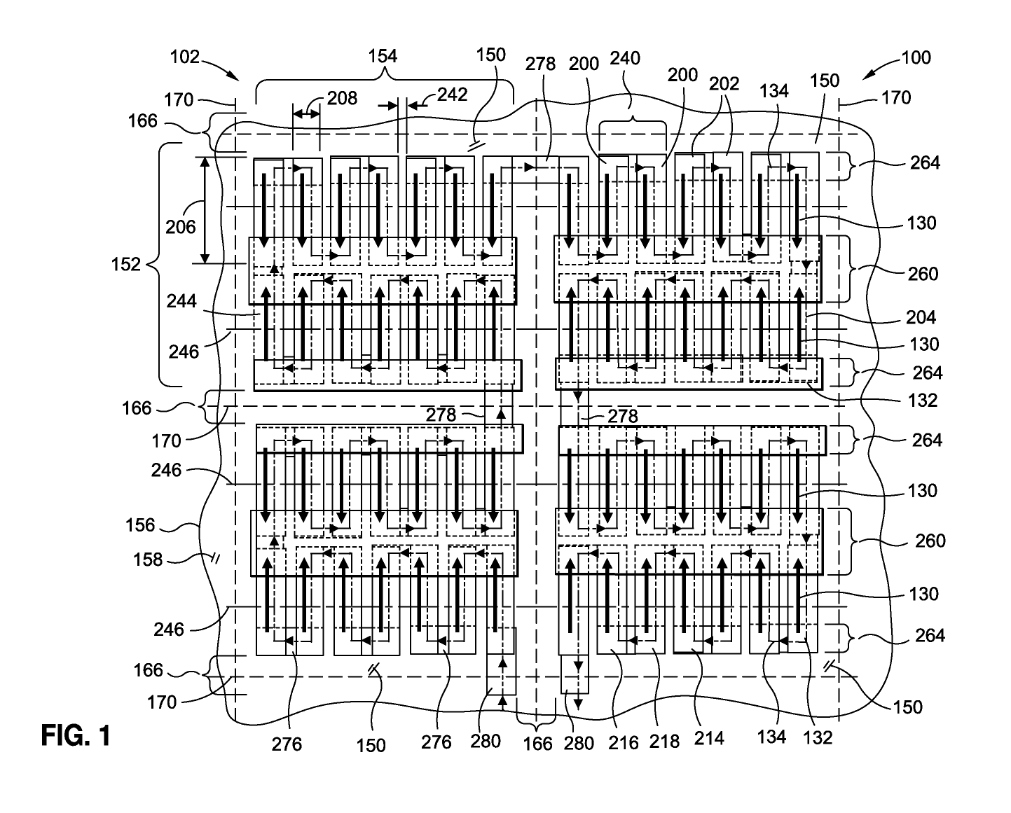

Referring now to the drawings wherein the showings are for purposes of illustrating preferred and various embodiments of the disclosure, shown in FIG. 1 is a top view of an embodiment of a flexible thermoelectric generator 102 having a series of thermoelectric legs 200 arranged in rows 244 on a substrate 158. The substrate 158 may include one or more substrate flex zones 166 separating the rows 244 of thermoelectric legs 200 and thereby defining rigid thermopile clusters 150. Each substrate flex zone 166 may define a relatively narrow region or zone of the substrate 158 along which the substrate 158 can flex or bend in an out-of-plane direction such that the thermoelectric generator 102 may conform to curved surfaces. The rigid thermopile clusters 150 define areas of the thermoelectric generator 102 that remain relatively rigid (e.g. substantially rigid, non-flexible, and/or non-bending) while the substrate 158 can flex along the substrate flex zones 166. Each one of the rigid thermopile clusters 150 may be bordered on one or more sides by a substrate flex zone 166 which may comprise a relatively free substrate space that allows for flexing or bending of the substrate 158. Although the thermoelectric generator 102 in FIG. 1 is shown as having four (4) rigid thermopile clusters 150, the thermoelectric generator 102 may be provided with substrate flex zones 166 that result in any number of rigid thermopile clusters 150.

Each one of the rigid thermopile clusters 150 may include at least one row 244 of thermocouples 240. A pair of thermoelectric legs 200 may define a thermocouple 240. One or more rows of thermocouples 240 may define a thermopile cluster 150. In an embodiment, a substrate flex zone 166 may separate a relatively rigid first thermopile cluster 150 from a relatively rigid second thermopile cluster 150. The substrate 158 may have greater flexibility in the substrate flex zone 166 in an out-of-plane direction relative to the out-of-plane flexibility of the substrate 158 in the first thermopile cluster 150 and in the second thermopile cluster 150. The longitudinal leg axis 204 of each one of the thermoelectric legs 200 may be oriented parallel to an upper surface 160 and/or lower surface 162 of the substrate 158 upon which the thermoelectric legs 200 are formed. In this regard, the thermoelectric legs 200 may be arranged in a planar, thin-film arrangement similar to the thermoelectric generator 102 embodiments disclosed in U.S. application Ser. No. 12/605,370 entitled PLANAR THERMOELECTRIC GENERATOR to Ingo Stark and filed on Oct. 25, 2009, the entire contents of which is incorporated by reference herein. The substrate flex zone 166 may be oriented in a generally straight-line direction. However, one or more of the substrate flex zones 166 may be provided in a curved direction or in any combination of straight-line and curved directions. In an embodiment, the substrate flex zones 166 may have a width of approximately 25 to 250 microns. However, the substrate flex zones 166 may be provided in a width larger than 250 microns or smaller than 25 microns.

As shown in FIG. 1, the thermoelectric legs 200 are formed of alternating material types and are arranged in one or more rows 244 on the substrate 158. The substrate 158 may have an upper substrate surface 160 and a lower substrate surface 162, either or both of which may include thermoelectric legs 200. The substrate 158 may be formed of an electrically insulating material having a relatively low thermal conductivity. In an embodiment, the substrate 158 may be formed of polyimide material such as Kapton®, commercially available from E. I. duPont de Nemours & Co., Inc. However, the substrate 158 may be formed of any suitable material having a relatively low thermal conductivity and which is preferably electrically insulating. The substrate 158 may be provided in any suitable substrate thickness 164 including, but not limited to, a substrate thickness 164 in the range of from approximately 5 microns to 100 microns. Preferably, the substrate 158 is provided in a substrate thickness 164 of approximately 12.5 microns although a thickness of approximately 7.5 microns may also be a suitable. The substrate 158 is preferably formed of a material that is mechanically stable at the elevated temperatures associated with deposition of semiconductor films and with the annealing process during deposition of the thermoelectric legs 200. The substrate 158 is preferably a relatively thin material having dimensional stability and which is resistant against chemicals in the process of structuring the thermoelectric legs 200 before and after deposition of the thermoelectric legs 200 on the substrate 158.

As indicated above, the thermoelectric legs 200 may be formed of alternating materials such as dissimilar materials. The dissimilar materials may comprise metallic material and/or semiconductor material such as n-type semiconductor material and/or p-type semiconductor material. In an embodiment, the thermoelectric legs 200 may be formed of alternating semiconductor material and metal material. The semiconductor material of the n-type and/or p-type thermoelectric legs 216, 218 may be a ternary compound of a bismuth-telluride-type semiconductor material. In an example not shown, one or more of the thermopile clusters 150 may be formed in a single layer arrangement of dissimilar thermoelectric legs 200 in a checkerboard pattern of p-type and n-type semiconductor legs 218, 216 such that the p-type and n-type semiconductor legs 218, 216 in one row 244 are aligned with the respective n-type and p-type semiconductor legs 216, 218 in an adjacent row 244. In an embodiment, metallic material of the thermoelectric legs 200 may include tungsten, chromium, gold, nickel, aluminum, silver, and/or copper, or any combination thereof or of any combination of other metallic materials.

The geometry of the thermoelectric legs 200 may be sized to maximize power output. In this regard, the thermoelectric legs 200 may be formed in a leg thickness 210 that may range from approximately 15 microns up to 100 microns or more and, preferably, in a thickness 210 of up to approximately 25 microns or more. The thermoelectric legs 200 may be provided in any suitable leg width 208 such as in the range of from approximately 10 microns up to approximately 500 microns. The thermoelectric legs 200 may be provided in a leg length 206 in the range of from approximately 50 microns to 500 microns although the leg length 206 may be provided in any range. For maximum power output the selection of the leg length 206 and the leg width 206 may be based on the condition of thermal match of all thermocouples with the environment of the thermocouples. Match the thermal configuration of the thermocouples to their environment regarding the heat couple plates, the substrate material, and also considering the heat source, the heat sink and the effect of the thermal resistance of the components.

In an embodiment, the p-type thermoelectric legs 218 may be electrically connected to adjacent ones of the n-type thermoelectric legs 216 at opposite leg ends 202 of the p-type thermoelectric legs 218 such that the n-type and p-type thermoelectric legs 216, 218 in a row 244 are electrically connected in series and thermally connected in parallel. However, the thermoelectric legs 200 may be electrically connected in series and/or partially connected in parallel to increase the redundancy of the electrical path 132 and reduce electrical resistance for higher electrical current. The rigid thermopile clusters 150 may be connected to each other in series, in parallel, or partially in series and parallel, as described in greater detail below.

In FIG. 1, each one of the thermoelectric legs 200 may have a leg axis 204 extending along a lengthwise direction of the thermoelectric leg 200. The lengthwise direction may be described as the direction of the electrical current through the thermoelectric leg 200 which is along a leg axis 204 extending between opposing lengthwise ends 202 of a thermoelectric leg 200, a lengthwise end 202 being a location where a thermoelectric leg 200 is electrically coupled to an adjacent thermoelectric leg. The leg axes 204 may be generally parallel to the substrate 158 surface and may be non-parallel to a row axis 246. The leg axes 204 of the thermoelectric legs 200 in at least one row 244 may be oriented in substantially perpendicular relation to the row axis 246 such that the series of thermoelectric legs 200 in a row 244 form a meandering pattern 134. The thermoelectric legs 200 in a row 244 may be oriented in substantially parallel relation to one another as shown in FIG. 1.

In an embodiment, the thermoelectric legs 200 may be coupled together by a plurality of metal bridges 276 formed on the substrate 158. The metal bridges 276 may electrically couple the leg ends 202 of the thermoelectric legs 200. In this regard, each one of the n-type and p-type legs has opposing leg ends 202. The legs ends may overlap the metal bridges 276 such that the metal bridges 276 electrically interconnect the p-type legs to adjacent ones of the n-type legs at opposite leg ends 202. The metal bridges 276 may be formed of an electrically conductive material such as tungsten, aluminum, and/or nickel. However, the metal bridges 276 may be formed of gold, silver, chromium, and/or copper, or any combination of any one of the above-mentioned materials or other materials.

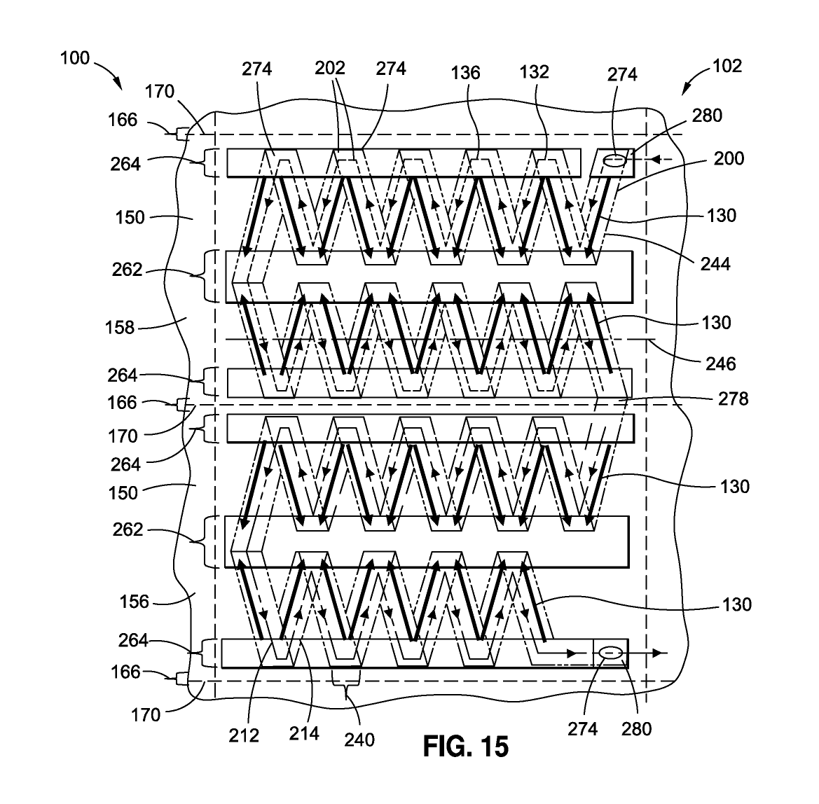

Advantageously, the non-parallel orientation of the leg axes 204 relative to the row axis 246 may improve the reliability of the thermoelectric generator 102. More specifically, the meandering pattern 134 of the thermoelectric legs 200 may reduce internal stresses of the structure of the thin-film which makes up the thermoelectric legs 200. Such internal stresses may result from a difference in the linear thermal expansion coefficient of the substrate 158 relative to the linear thermal expansion coefficient of the thermoelectric legs 200 at elevated temperatures during the fabrication process. In addition, the meandering pattern 134 of the thermoelectric legs 200 may minimize the buildup of internal stresses and allow for absorption of such internal stresses due to the relatively short length of the thermoelectric legs 200 as well as due to the constantly changing lateral orientation of the thermoelectric legs 200 in the meandering pattern 134 (FIG. 1) or zig-zag pattern 136 (FIG. 15). The net result of the meandering pattern 134 or zig-zag pattern 136 is an increase in the mechanical stability of the thermoelectric generator 102 and increased reliability of operation.

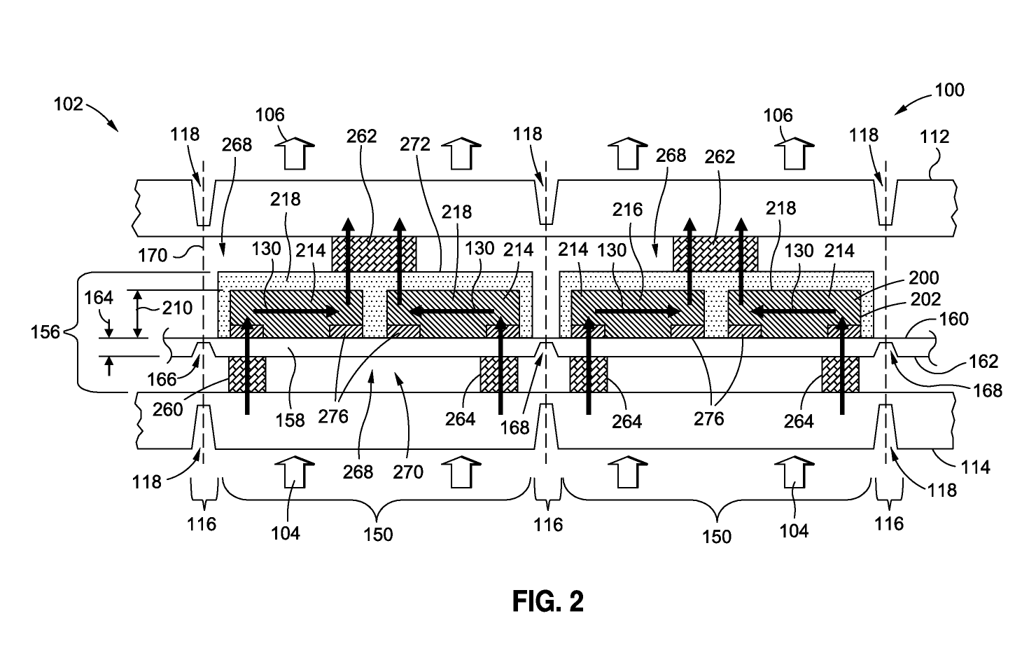

Referring to FIGS. 1-2, the thermoelectric generator 102 may include at least one thermally conductive strip 260 located on at least one side of the substrate 158 to create a pattern of lateral temperature differentials as described in the above-referenced U.S. application Ser. No. 12/605,370 entitled PLANAR THERMOELECTRIC GENERATOR. In addition, the thermoelectric generator 102 may include at least one top heat couple plate 112 and/or at least one bottom heat couple plate 114 and which may be formed of material having a relatively high thermal conductivity. For example, the top and/or bottom heat couple plate 112, 114 may be formed of stainless steel, aluminum, or other materials. The top and/or bottom heat couple plate 112, 114 and the thermally conductive strips 260 may provide a thermal path for heat transfer to and from the thermocouples 240. For example, the top and/or bottom heat couple plate 112, 114 and the thermally conductive strips 260 may provide for heat input from a heat source 104 such as from the skin surface of a living body, the surface of a heat pipe or warm pipe, or from any other heat source 104. In addition, the top and/or bottom heat couple plate 112, 114 and the thermally conductive strips 260 may provide for heat rejection to a heat sink 106 such as ambient air or to another type of heat sink 106. In some examples, the thermally conductive strips 260 may be formed of material having a relatively high thermal conductivity. For example, the thermally conductive strips 260 may be formed of polymeric material having a thermal conductivity of up to approximately 20 W/m K or more. In some examples, the top heat couple plate 112 and/or bottom heat couple plate 114 may be formed as a laminate (not shown) comprising metal foil (e.g., having a high peel strength) laminated or plated onto a plastic layer to form a flex board. Such a metal foil may be structured in a manner to make the laminate more flexible.

One or more thermally conductive strips 260 may be located on a side of the substrate 158 defined by the upper substrate surface 160, and/or one or more thermally conductive strips 260 may be located on a side of the substrate 158 defined by the lower substrate surface 162. A pair of thermally conductive strips 260 may be generally aligned with opposite lengthwise leg ends 202 of the thermoelectric legs 200 in a row 244 such that one lengthwise leg end 202 is in thermal contact with the top heat couple plate 112 and the opposite lengthwise leg end 202 is in thermal contact with the bottom heat couple plate 114. The thermally conductive strips 260 may be generally aligned with the row axes 246 as shown in FIG. 1. In this regard, the thermally conductive strips 260 may be generally aligned with and positioned over the opposing leg ends 202 of the thermoelectric legs 200 in at least one row 244 of at least one of the rigid thermopile clusters 150. Some of the substrate flex zones 166 may be oriented generally parallel or generally perpendicular to the row axes 246. The thermally conductive strips 260 may be thermally coupled to the leg ends 202 of the thermoelectric legs 200 but non-electrically coupled to the thermoelectric legs 200. For example, an electrically insulating layer 272 may be provided over the thermoelectric legs 200 of a rigid thermopile cluster 150. The electrically insulating layer 272 may electrically insulate the thermoelectric legs 200 from the thermally conductive strips 260. Although FIG. 2 illustrates the dual thermally conductive strips 262 and the single thermally conductive strips 264 thermally coupling the leg ends 202 of the thermoelectric legs 200 to a nearest one of a top heat couple plate 112 and a bottom heat couple plate, the thermoelectric generator 102 may be provided in a configuration wherein the top heat couple plate 112 and/or the bottom heat couple plate 114 are in direct physical contact with one of the substrate 158 surfaces.

The thermally conductive strips 260 may define thermal gaps 268 between the thermoelectric legs 200 and the top heat couple plate 112 and/or the bottom heat couple plate 114. The thermal gaps 268 may cause heat to flow along a lengthwise direction 130 through the thermoelectric legs 200 generally parallel to the substrate 158 surfaces as shown in FIG. 2. The thermoelectric generator 102 may be configured to maximize the difference in thermal conductance of the thermally conductive strips 260 relative to the thermal conductance of the thermal gaps 268 so that the temperature difference across the thermopile is maximized which may improve the power output of the thermoelectric generator 102. Filling the thermal gaps 268 with a relatively low thermal conductivity material may increase the power output of the thermoelectric generator 102. In some examples, the thermal gaps 268 may be filled with a solid, a liquid or a gaseous material having a relatively low thermal conductivity. For example, the thermal gaps 268 may be filled with air, argon, krypton, xenon, or the thermal gaps 268 may be filled with foam such as polyurethane foam to increase the power output of the thermoelectric generator 102. In some example, the thermal gaps 268 within a thermopile cluster 150 may be filled with material having a relatively low thermal conductivity such as by using screen printing. Thermal gaps 268 filled with gas may allow for flexing along the flex zones 166. If the thermal gaps 268 are filled with a relatively stiff material, such material may be kept out of the flex zones 166 to allow for the flexing of the substrate along the flex zones 166. As indicated above, the heat flow may cause electricity to flow along an electrical path 132 such as in a meandering pattern 134 through the thermoelectric legs 200. The electrical path 132 may be oriented generally parallel to the substrate 158 surfaces as shown FIG. 1. In a further embodiment described below, the thermoelectric legs 200 may be arranged such that heat flow results in electricity flowing in a zig-zag pattern 136 through the thermoelectric legs 200 as shown in FIG. 15.

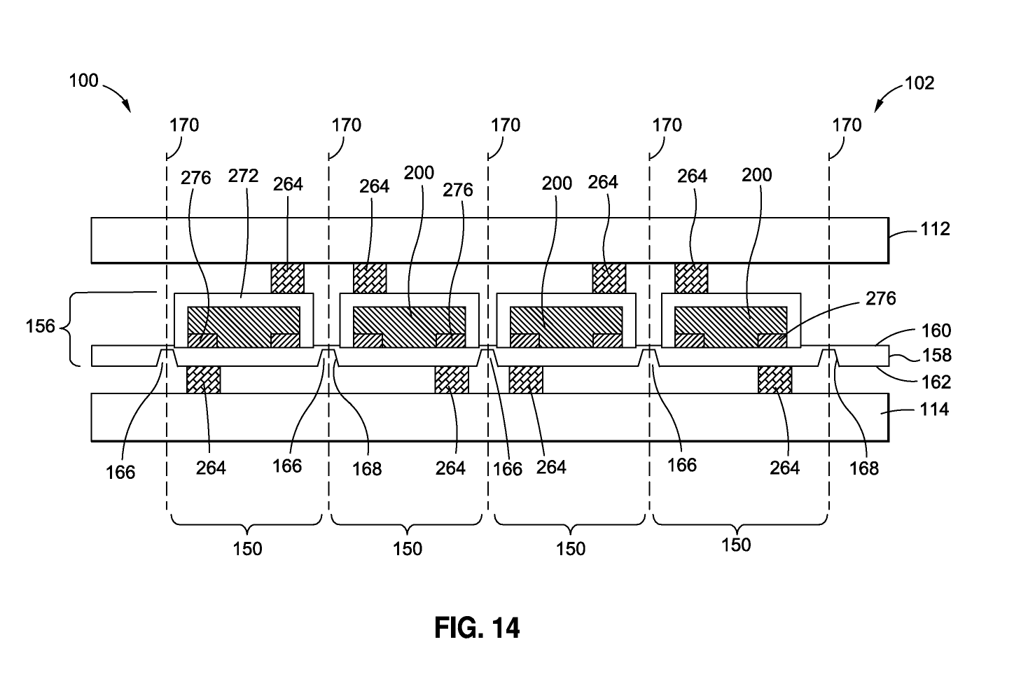

The thermally conductive strips 260 may be provided as single thermally conductive strips 264 and/or the thermally conductive strips 260 may be provided as dual thermally conductive strips 262. For example, a thermoelectric generator 102 may include at least one single thermally conductive strip 264 thermally coupling a top heat couple plate 112 to the leg ends 202 of the thermoelectric legs 200 in a single one of the rows 244, or a single thermally conductive strip 264 may thermally couple a bottom heat couple plate 114 to the leg ends 202 of the thermoelectric legs 200 in a single one of the rows 244. FIG. 2 illustrates single thermally conductive strips 264 sandwiched between the bottom heat couple plate 114 and the lower substrate surface 162. In an embodiment, a thermoelectric generator 102 may include at least one dual thermally conductive strip 262 thermally coupling a top heat couple plate 112 and/or a bottom heat couple plate 114 to the leg ends 202 of the thermoelectric legs 200 in two rows 244 of thermoelectric legs 200. For example, FIG. 2 illustrates dual thermally conductive strips 262 sandwiched between the top heat couple plate 112 and the leg ends 202 of the thermoelectric legs 200 formed on the upper substrate surface 160. Alternating arrangements of single thermally conductive strips 264 and dual thermally conductive strips 262 may be provided on the respective upper and lower substrate surfaces 160, 162, or vice versa. For decreased flexibility of the thermoelectric generator 102, the thermoelectric generator 102 may be provided with only dual thermally conductive strips 262. For increased flexibility, the thermoelectric generator 102 may be provided with more single thermally conductive strips 264 than dual thermally conductive strips 262, or the thermoelectric generator 102 may be provided with all single thermally conductive strips 264 (e.g., see FIG. 14).

For increased mechanical stability and simplification of the thermoelectric generator 102, one or more of the thermally conductive strips 260 may be formed directly on one side of the substrate 158 such as on the upper substrate surface 160 or on the lower substrate surface 162. Alternatively, one or more of the thermally conductive strips 260 may be integrally formed as part of the top heat couple plate 112 and/or the bottom heat couple plate 114. Even further, one or more of the thermally conductive strips 260 may be formed as a separate layer that may be positioned between the substrate 158 and the top and/or bottom heat couple plate 112, 114 during the assembly of the thermoelectric generator 102. As shown in FIG. 1, the thermally conductive strips 260 may be provided into physically separate segments in order to allow the thermoelectric generator 102 to bend or flex along a flex zone along a direction perpendicular or orthogonal to the lengthwise direction of the thermally conductive strips 260. For example, FIG. 1 illustrates each one of the rigid thermopile clusters 150 having separate thermally conductive strip 260 segments that do not extend across the substrate flex zones 166.

In the thermoelectric generator 102, each thermoelectric leg 200 may define a leg axis extending along a lengthwise direction of the thermoelectric leg 200 and oriented non-parallel to the row axis 246 and parallel to the substrate surfaces 160,162. In the present disclosure, the lengthwise direction may be described as the direction extending between opposing lengthwise ends 202 of the thermoelectric leg 200. Each one of the thermoelectric legs 200 has opposite lengthwise ends 202. The lengthwise end 200 of at least one of the thermoelectric legs 200 may be electrically connected to an adjacent thermoelectric leg 200 at an electrical connection defining at least one plane that is parallel to the plane of the electrical connection of the opposite lengthwise end of the at least one thermoelectric leg 200 to a different thermoelectric leg 200. The plane of each one of the electrical connections may be parallel to the substrate surfaces 160, 162. The electrical connections between the at least one thermoelectric legs 200 and the adjacent legs 200 may be confined to or located adjacent to the lengthwise ends 202 of the at least one thermoelectric leg 200.

As mentioned above, a thermopile cluster 150 may include at least one pair of thermally conductive strips 160. One of the thermally conductive strips 160 may be located on a side of the substrate 158 defined by the upper substrate surface 160 and physically contacting the top heat couple plate 112. The other one of the thermally conductive strips 160 may be located on an opposite side of the substrate 158 as defined by the lower substrate surface 162 and physically contacting the bottom heat couple plate 114. The pair of thermally conductive strips 160 may be aligned with opposite lengthwise ends 202 of the thermoelectric legs 200 in a row 244 such that one lengthwise end 202 of the thermoelectric legs 200 is in thermal contact with the top heat couple plate 112 and the opposite lengthwise end of the thermoelectric legs 200 is in thermal contact with the bottom heat couple plate 114. The thermally conductive strips 160 may define thermal gaps between the thermoelectric legs 200 and the top and bottom plates 112, 114 causing heat to flow lengthwise through each one of the thermoelectric legs 200 along a direction parallel to the substrate surfaces 160, 162 wherein the heat flows from one end 202 of the thermoelectric leg 200 overlapped by a thermally conductive strip 160 to an opposite end 202 of the thermoelectric leg 200 overlapped by a different thermally conductive strip 160. An electrically insulating layer 272 may physically contact and physically separate the thermoelectric legs 200 from the thermally conductive strip 160 physically contacting the top heat couple plate 112 or the bottom heat couple plate 114.

Referring to FIG. 2, one or more of the single thermally conductive strips 264 and dual thermally conductive strips 262 may be mounted on at least one side of the substrate 158 using a thermally conductive adhesive 266. The thermally conductive adhesive 266 may be flexible or semi-flexible. Such a flexible or semi-flexible adhesive may provide good thermal contact between the thermally conductive strips 260 and the heat couple plates 112 and 114, the thermoelectric legs 200, or the substrate 158. In addition, the flexible or semi-flexible adhesive for mounting the thermally conductive strips 260 may provide some measure of stress relief for when the thermoelectric generator 102 is bent or flexed. During bending of the thermoelectric generator 102, the foil assembly 156 (e.g., the substrate 158 with thermoelectric legs 200) may be subject to tensile forces that may generally increase along one direction from the middle of the foil assembly 156 toward an outer surface 304 of the foil assembly 156, and compression forces that may generally increase along an opposite direction. By minimizing the thickness of the components that make up the thermoelectric generator 102, the tensile forces and/or compressive forces may be minimized. For example, by minimizing the width and height of the thermally conductive strips 260, the tensile forces and/or compressive forces may be minimized during bending of the thermoelectric generator 102. In some example, a thermally conductive strip 160 may be formed by electroplating material onto one or more substrate surfaces 160, 162 or as a lamination of one more lamination strips onto one or more substrate surfaces 160, 162 and/or onto the top heat couple plate 112 and/or the bottom heat couple plate 114. Thermally conductive strips 160 may also be provided as stamped metal foils.

In FIG. 2, the substrate flex zone 166 comprises a region of localized thinning in at least one of the upper and lower substrate surfaces 160, 162. The substrate flex zones 166 may be provided by locally reducing the substrate thickness 164 in the substrate flex zones 166 relative to the substrate thickness 164 in the rigid thermopile clusters 150. For example, FIG. 2 illustrates localized thinning along the lower substrate surface 162. However, the substrate 158 may be locally thinned along the upper substrate surface 160 and/or along both the upper and the lower substrate surfaces 160, 162. Local substrate thinning may be performed by selective etching of at least one substrate surface 160, 162, or by mechanical cutting such as by forming notches and/or grooves 168 in at least one substrate surface 160, 162. Substrate thinning may also be performed by laser treatment to locally thin the substrate 158 and/or form holes, slots, grooves, and/or notches, or other mechanical features that locally thin the substrate 158. Substrate flex zones 166 may also be performed by omitting a coating (e.g., a photo resist coating) on at least one of the substrate surfaces 160, 162 such as during the foil assembly 156 process. The substrate flex zones 166 may be in the same plane as the substrate 158. In some examples, the substrate flex zones 166 may contain only substrate 158 (e.g., Kapton foil) with no localized thinning of the substrate 158 (e.g., no notches or grooves). In addition, substrate flex zones 166 may be formed by omitting any thermopile structure in the substrate flex zones 166 such as omitting any thermoelectric legs 200 or coatings in the substrate flex zones 166, and allowing only periodically-located electrical connections in the substrate flex zones 166 such as the electrical interconnects 278 connecting the adjacent thermopile clusters 150. Such electrical interconnects 278 may electrically connect a row 244 of thermoelectric legs 200 in one thermopile cluster 150 to a row 244 of thermoelectric legs 200 in another thermopile cluster 150. An electrical interconnect 278 may be formed on the substrate 158 and may extend across a substrate flex zone 166 to electrically connect a leg end 202 of a thermoelectric leg 200 in a first thermopile cluster 150 to a leg end 202 of a thermoelectric leg 200 in a second thermopile cluster 150. Advantageously, each thermopile cluster 150 may be rigid with regard to thin film systems (e.g., semiconductor, metal, passivation layer, thermal strips). The flexibility of each thermopile cluster 150 may be dependent to a high degree on the construction of the heat couple plates 112, 114 (e.g., material composition and material thickness) and the ability of the heat couple plates 112, 114 to flex (e.g., by including notches etc.) Although not shown, one or more of the thermopile clusters 150 may optionally be provided with a mechanical frame (e.g., a picture frame) circumscribing the thermopile cluster 150 to mechanically stabilize and prevent flexing and/or twisting of the thermopile cluster 150. Such a frame may be formed of material having a low thermal conductivity (e. g. sealant). In still other embodiments, a thermopile cluster 150 may be stiffened and mechanically stabilized against flexing by the application of one or more coating on the thermopile cluster 150.

In some examples, the top heat couple plate 112 and/or bottom heat couple plate 114 may include a plate flex zone 116. FIG. 2 illustrates the plate flex zones 116 comprised of areas of reduced thickness in the heat couple plates 112, 114 to facilitate bending of the heat couple plates 112, 114. In some example, the plate flex zones 116 may comprise a plate notch or groove 118 locally formed in the top and/or bottom heat couple plate 112, 114 to facilitate out-of-plane bending of the heat couple plates 112, 114. The top and/or bottom heat couple plate 112, 114 may be substantially rigid and non-flexible in an out-of-plane direction in regions other than the plate flex zones 116. In some embodiments, one or more of the plate flex zones 116 may be substantially aligned with the substrate flex zones 166 as shown in FIG. 2. In an embodiment not shown, the top heat couple plate 112 and/or bottom heat couple plate 114 may each be divided into individual heat couple plate segments. Each heat couple plate segment may be associated with or thermally coupled to a given rigid thermopile cluster 150. The individual heat couple plate segments may be physically separate from one another although the edges of the individual heat couple plates segments may contact adjacent heat couple plate segments.

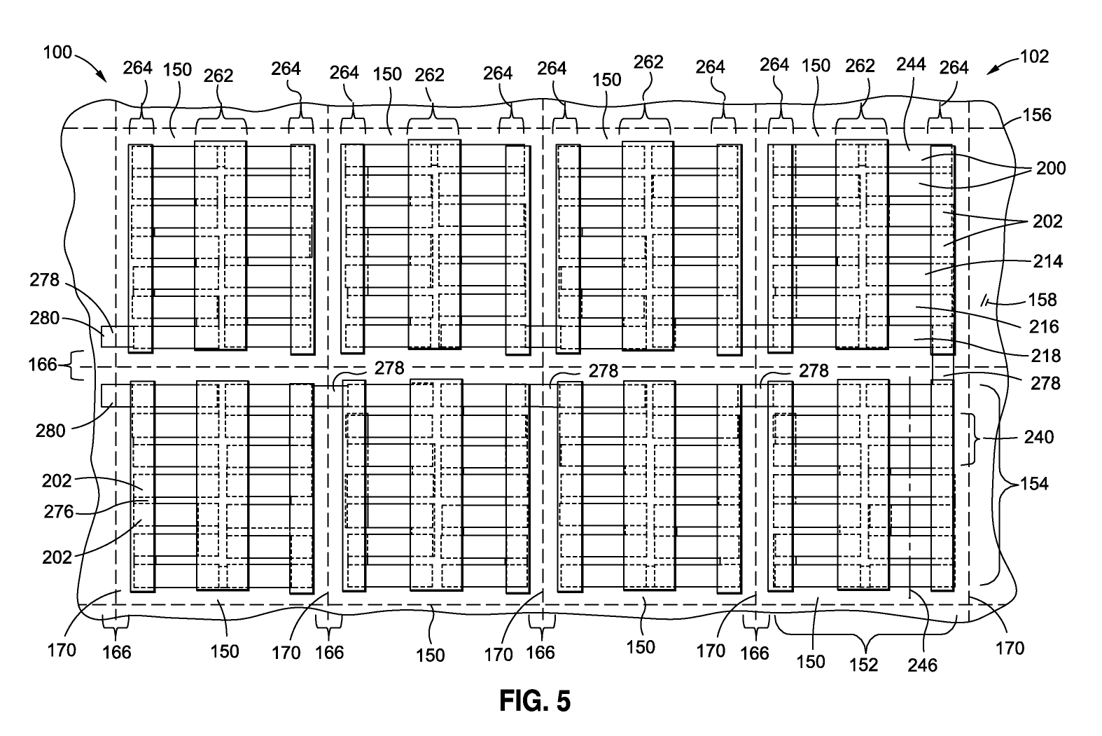

Advantageously, each thermopile cluster 150 may be provided in a generally compact arrangement such that each thermopile cluster 150 has increased stability and rigidness. In an embodiment, each thermopile cluster 150 may be formed with a relatively high density of thermoelectric legs 200 onto the substrate 158 surfaces with minimal leg gaps 242 between the thermoelectric legs 200. In an embodiment, the leg gaps 242 may be between approximately 5 μm to 50 μm, although larger or smaller leg gaps are contemplated. The thermopile clusters 150 may be configured to provide maximum coverage of thermoelectric legs 200 and metal bridges 276 connecting the thermoelectric legs 200. In some examples, the thermopile clusters 150 may have a cluster width 154 and cluster length 152 (e.g., a footprint) in the range of from approximately 0.3 mm×0.3 mm to approximately 5 mm×5 mm for flexing in two directions as show in the embodiment illustrated in FIG. 1. In such an arrangement, the substrate 158 may include at least two of the substrate flex zones 166 oriented non-parallel (e.g., substantially perpendicular) to one another to define at least four (4) thermopile clusters 150 as shown in FIG. 1. In other examples, the thermopile clusters 150 may have a cluster width 154 and cluster length 152 in the range of from approximately 0.3 mm×1.5 mm to approximately 5 mm×30 mm for flexing in one direction (e.g., see FIG. 5). However, the thermopile clusters 150 may be provided in any size (e.g., length and width), without limitation.

In some examples, the thermopile clusters 150 may be provided with a relatively large thickness of n-type and p-type thermoelectric legs 214, 216 that make up the thin-film thermocouples 240. As indicated earlier, the thermoelectric legs 200, metal bridges 276, and electrical interconnects 278 may be covered with a coating such as annealed photo resist for sealing of the thermoelectric legs 200 to the substrate 158. Some embodiments of the thermoelectric generator 102 may be provided as a double layer of thermoelectric legs 200 separated by an electrically insulating layer 272 as disclosed in the above-referenced U.S. application Ser. No. 12/605,370 entitled PLANAR THERMOELECTRIC GENERATOR. In order to improve the reliability and durability of the electrical interconnects 278 between the thermopile clusters 150, flexible electrical adhesive (not shown) may be applied parallel to the electrical interconnects 278 bridging over the substrate flex zones 166 to electrically connect thermopile cluster 150 to thermopile cluster 150. Alternatively, flexible electrical adhesive may be used to bridge over the substrate flex zones 166 as the sole material electrically interconnecting the thermopile clusters 150. In some examples, the thermopile clusters 150 may be separated from one another such that the substrate is omitted in the substrate flex zones 166, and adhesive is used to physically and electrically connect the thermopile clusters 150. In this regard, a frame may extend along the flex lines and the substrate 158 may be completely removed within the substrate flex zones 166 such that there is no direct connection between the thermopile clusters 150, but there still may be a flexible connection using flexible material (e.g., adhesive) in the substrate flex zones 166 to allow for stretching in the in-plane direction.

Although the present disclosure is described in the context of a flexible thermoelectric generator 102, the structural arrangement disclosed herein may be optionally implemented as a flexible heat flux sensor for conforming to curved surfaces. For example, the above-described structural arrangement of thermopile clusters 150 separated by substrate flex zones 166 and plate flex zones 116 may be implemented in a heat flux sensor for measuring heat flow or heat gradient along a surface. Such a heat flux sensor may be implemented for measuring heat flow along a wearer's body surface, measuring energy consumption correlated to a wearer's activity level, or to provide heat flow diagnostics and/or to measure heat losses in industrial applications. In some embodiments, each thermopile cluster 150 may have separate terminal pads 280 so that a lateral thermopile cluster 150 arrangement may form a two-dimensional heat flux sensor array to allow for measuring the heat flow distribution within an area.

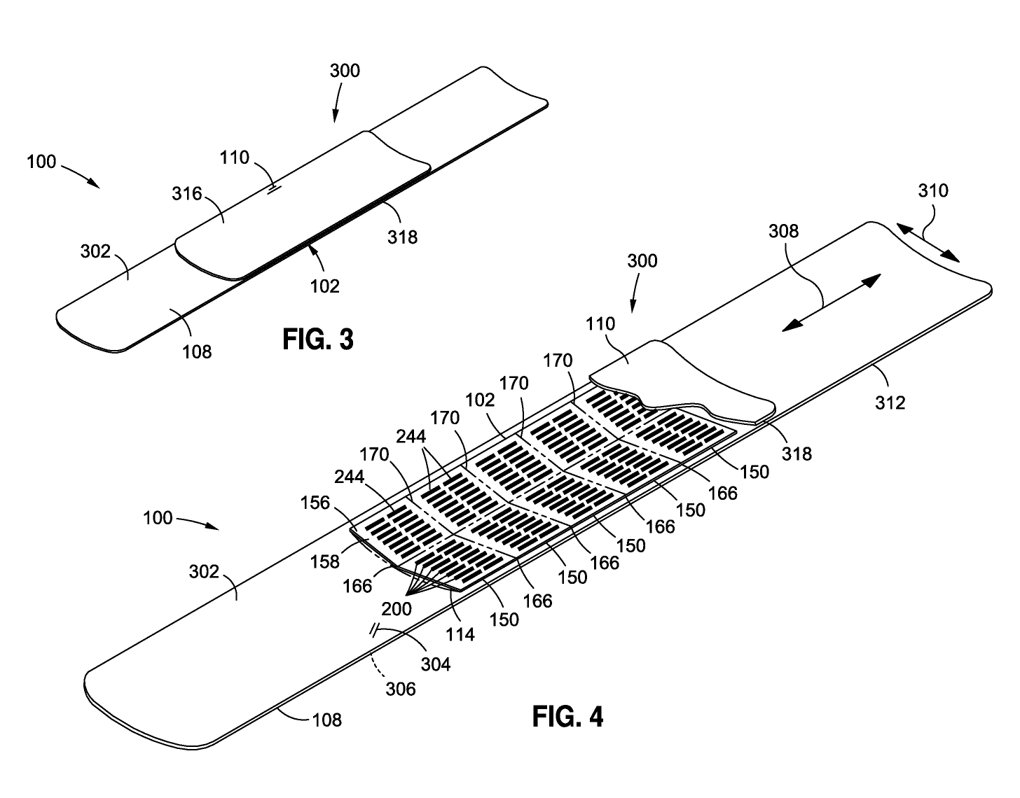

FIG. 3 shows an embodiment of a thermoelectric generator system 100 integrated into a band element 300. The band element is configured as a flexible bi-stable spring band 302 having an outer band 316 covering a flexible thermoelectric generator 102. The bi-stable spring band 302 represents one example of a wide variety of different wearable applications into which a flexible thermoelectric generator 102 may be integrated for converting body heat from humans and/or animals into electricity. As indicated above, the thermoelectric generator system 100 is configured to flex or bend in one or more directions to conform to a curved surface for improved heat transfer. The flexibility of the thermoelectric generator system 100 may allow the device to flex and maintain contact with the wearer's skin during normal body movements which may provide continuity of heat flow through the thermoelectric generator 102 and resulting in consistent and reliable thermoelectric performance and comfort for the wearer. In this regard, the flexible thermoelectric generator 102 may be easily integrated into healthcare and wellness products. In addition, the flexible thermoelectric generator 102 may be integrated into all types of clothing and apparel such as patches, jackets, headbands, wristbands, armbands, and other items which may be made from textiles, plastics, and/or rubber materials. For example, the flexible thermoelectric generator 102 may be integrated into wearable applications similar to those disclosed in U.S. application Ser. No. 13/648,277 entitled WEARABLE THERMOELECTRIC GENERATOR SYSTEM 100 to Ingo Stark and filed on Oct. 9, 2012, the entire contents of which is incorporated by reference herein.

The ability of the flexible thermoelectric generator 102 to flex or bend around curved surfaces may improve the aesthetics of a wearable device relative to conventional thermoelectric generators which are generally rigid and flat. Furthermore, the flexible thermoelectric generator 102 may be less visible, have a lower weight, and may occupy a reduced amount of space relative to conventional devices. For example, as indicated above, the flexible thermoelectric generator system 100 may be provided in a relatively low profile with a total thickness in the range of from approximately 0.2 mm to 0.5 mm although the flexible thermoelectric generator 102 may be provided in smaller or larger thicknesses. The heat couple plates 112, 114 may be formed of robust and corrosion-resistant material such as stainless steel, aluminum foil, or other materials. The heat couple plates 112, 114 may be provided in relatively small thicknesses down to 100 um or less. For industrial applications, a relatively thin and flexible thin-film thermoelectric generator system 100 may be conveniently wrapped around a curved surface. For example, a flexible thermoelectric generator system 100 may be mounted to a warm pipe such as in a factory. However, the flexible thermoelectric generator 102 may be into any one of a variety of different industrial applications and is not limited to mounting on a warm pipe.

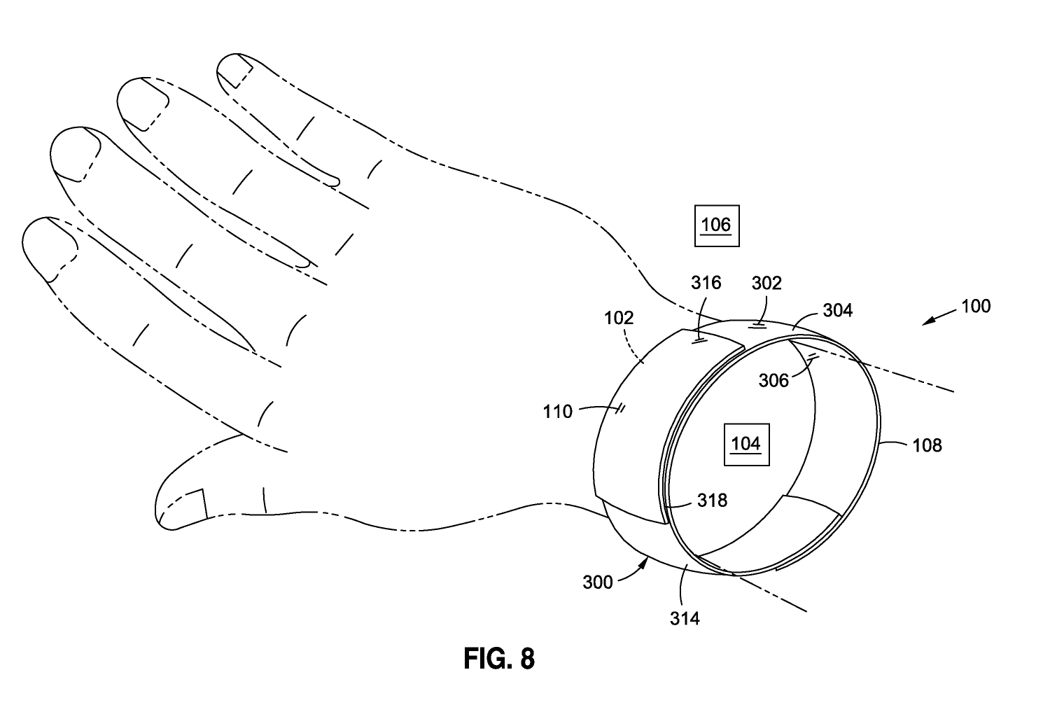

Referring to FIG. 4, shown is partially cutaway perspective view of the thermoelectric generator system 100 illustrated in FIG. 3. FIG. 4 illustrates a foil assembly 156 having rigid thermopile clusters 150 each having rows 244 of thermoelectric legs 200 formed on a substrate 158. The substrate 158 is shown as being bent along a substrate flex zone 166 which is oriented parallel to a long axis 308 or direction of the bi-stable spring band 302. The flexing of the foil assembly 156 along the substrate flex zone 166 accommodates the slightly concave outer surface 304 (e.g. in the transverse direction) of the bi-stable spring band 302. The wearable bi-stable spring band 302 may be sized and configured to be worn on a body part of a human body or animal body. For example, the bi-stable spring band 302 may be formed of metallic and/or non-metallic material and may be worn as a wrist band (e.g., a slap bracelet), an arm band, a leg band, or on any other body part. The ability of the flexible thermoelectric generator 102 to transition from a straight shape 312 (FIGS. 3-4) to a curved shape 314 (FIG. 8) greatly enhances the thermal coupling between the body surface and the flexible thermoelectric generator 102.

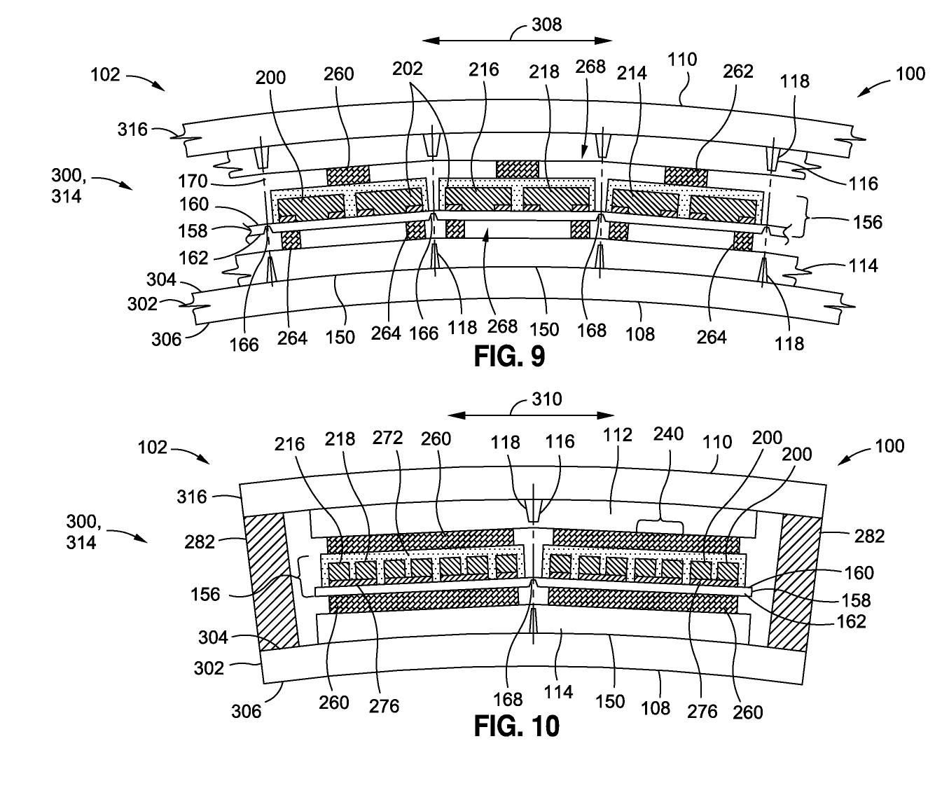

The bi-stable spring band 302 may be stable in the straight shape 312 shown in FIGS. 3-4 and may also be stable in the curved shape 314 as shown in FIG. 8. The bi-stable spring band 302 is stable in the sense that the bi-stable spring band 302 maintains its shape in equilibrium without the application of external force to hold the shape of the bi-stable spring band 302. In this regard, the bi-stable spring band 302 has a long axis 308 that is substantially straight when the bi-stable spring band 302 is in the straight shape 312 (FIGS. 3-4). The long axis 308 is curved when the bi-stable spring band 302 is in the curved shape 314 (FIG. 8). The bi-stable spring band 302 may have an outer surface 304 that is slightly concave (FIG. 7) when the bi-stable spring band 302 is in the straight shape 312 and the outer surface 304 is slightly convex (FIG. 10) when the bi-stable spring band 302 is in the curved shape 314. In this regard, the inner surface 306 of the bi-stable spring band 302 is slightly convex when the bi-stable spring band 302 is in the straight shape 312 and the inner surface 306 is slightly concave when the bi-stable spring band 302 is in the curved shape 314. The flexible thermoelectric generator 102 as integrated into bi-stable spring band 302 is capable flexing in two directions (i.e., two-dimensional flexing) including the long direction 308 and the transverse direction 310 of the bi-stable spring band 302.

FIG. 5 is a top view of an embodiment of a thermoelectric generator 102 as may be integrated into a band element 300 (e.g., a bi-stable spring band 302). Shown is the foil assembly 156 having eight (8) rigid thermopile clusters 150. However, the foil assembly 156 may include any number of rigid thermopile clusters 150. The rigid thermopile clusters 150 may be separated by the substrate flex zones 166 which may be represented by flex lines 170 shown in dashed font. Although each rigid thermopile cluster 150 is shown having two rows 244 of thermoelectric legs 200 formed on the substrate 158, each rigid thermopile cluster 150 may have any number of rows 244 of thermoelectric legs 200. In the embodiment shown, each one of the rigid thermopile clusters 150 includes a dual thermally conductive strip 262 in the center of the rigid thermopile cluster 150. In addition, thermopile clusters 150 may each include a pair of single thermally conductive strips 264 overlapping the leg ends 202 of thermoelectric legs 200. However, the flexible thermoelectric generator 102 may include any arrangement of single thermally conductive strips 264, dual thermally conductive strips 262, or any combination thereof. The adjacent thermopile clusters 150 may be electrically connected using an electrical interconnect 278 and/or using a flexible electrically conductive adhesive, as described above.

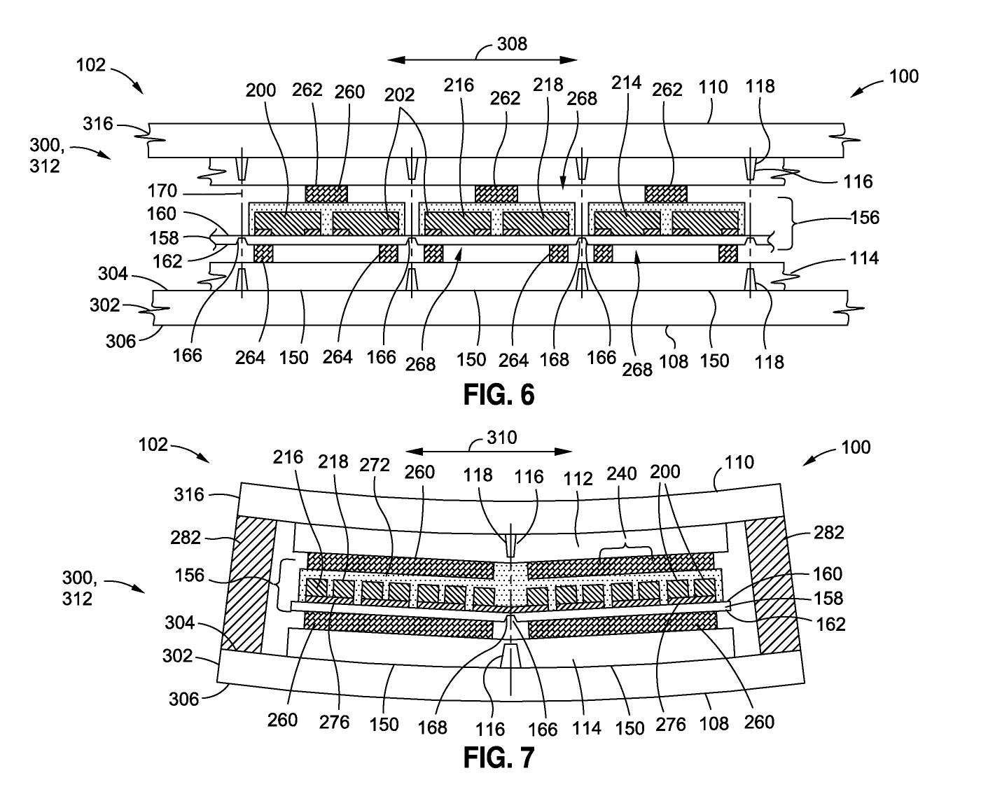

FIG. 6 is a sectional view in a longitudinal direction 308 of the thermoelectric generator system 100 in the straight shape 312 as shown in FIG. 4. The thermoelectric generator system 100 includes a thermoelectric generator 102 sandwiched between the outer band 316 and the bi-stable spring band 302. The thermoelectric generator system 100 may include a top heat couple plate 112 and a bottom heat couple plate 114 respectively mounted to the outer band 316 and the bi-stable spring band 302. Each one of the top and bottom heat couple plates 112, 114 may include plate flex zones 116 which may be generally aligned with the substrate flex zones 166 in the substrate 158. Dual thermally conductive strips 262 may be positioned between the thermoelectric legs 200 and the top heat couple plate 112 as mentioned above. Single thermally conductive strips 264 may be positioned between the substrate 158 and the bottom heat couple plate 114. The thermal gaps 268 may cause heat to flow in a lengthwise direction 130 through the thermoelectric legs 200 along a direction generally parallel to the substrate 158. Thermal insulation 270 may be provided within the thermal gaps 268 to maximize the temperature difference across the thermopile which may improve the power output of the thermoelectric generator 102.

In an embodiment not shown, the bi-stable spring band 302 may be used as a heat exchanger 110 having a flexible thermoelectric generator 102 mounted thereto. The bi-stable spring band 302 may thereby augment the amount of surface area of the heat couple plates 112, 114 resulting in a higher power output of the thermoelectric generator 102. In some examples, the bi-stable spring band 302 may be thermally insulated on an inner surface of the spring band 302 which may be in contact with wearer's skin such that the wearer's body heat will flow primarily through the thermoelectric generator 102. In a further embodiment not shown, the thermoelectric generator 102 may include a pair of bi-stable spring bands 302 having a thermal insulating layer 318 sandwiched therebetween. The pair of bi-stable spring bands 302 may act as heat collector 108 and heat exchanger 110, respectively. A flexible thermoelectric generator 102 may be integrated between the bi-stable spring bands 302 in areas without thermal insulation 270. In a still further embodiment not shown, the thermoelectric generator system 100 may be provided without heat couple plates. In this regard, the foil assembly 156 (e.g., the substrate 158 with thermoelectric legs 200) may be mounted directly on a heat exchanger 110/heat collector 108 such as directly on a bi-stable spring band 302. In any one of the embodiments disclosed herein, a metalized pattern (not shown) may be provided on a flexible heat collector and/or on a heat exchanger foil for stiffening the thermopile cluster 150 and improving the spreading of heat.

FIG. 7 is a sectional view in a transverse direction 310 of the thermoelectric generator system 100 in the straight shape 312 as shown in FIG. 4 and showing the substrate 158 bent along the substrate flex zone 166 to accommodate the slightly concave curvature of the bi-stable spring band 302 along the transverse direction 310. As can be seen, the outer band 316 may function in a manner similar to the bi-stable spring band 302 wherein the outer band 316 may be stable in a straight shape 312 (FIGS. 6-7) and may also be stable in a curved shape 314 (FIGS. 9-10). In an embodiment, the heat couple plates 112, 114 may be generally rigid in order to provide mechanical stability to the rigid thermopile clusters 150 to prevent undue flexing of the thermoelectric legs 200. However, in other embodiments, the heat couple plates 112, 114 may be flexible. The heat couple plates 112, 114 may be mounted to the outer band 316 and the bi-stable spring band 302 such as by using a flexible, thermally conductive adhesive 266 that may compensate for changes in curvature of the outer band 316 and bi-stable spring band 302 as the thermoelectric generator 102 is flexed between the curved shape 314 and the straight shape 312. The thermoelectric generator system 100 may optionally include a sealant 282 that may be applied to the perimeter edges of the outer band 316 and bi-stable spring band 302 to protect the flexible thermoelectric generator 102 against the environment and to provide a barrier to moisture, dirt, chemicals, and other contaminants. Furthermore, the sealant 282 may enhance the mechanical stability of the thermoelectric generator system 100. The sealant 282 preferably has a relatively low thermal conductivity to reduce the shunting of heat from the bi-stable spring band 302 through the sealant 282 and into the outer band 316.

FIG. 8 shows the flexible bi-stable spring band 302 in a curved shape 314 wrapped around the wrist of a wearer. In the curved shape 314, the opposing ends of the bi-stable spring band 302 may overlap. Advantageously, the ability of the flexible thermoelectric generator 102 to bend and flex along the substrate flex zones 166 and plate flex zones 116 greatly enhances the thermal coupling between the wearer's body surface and the flexible thermoelectric generator 102. The enhanced thermal coupling may improve power output of the thermoelectric generator 102.

FIG. 9 is a sectional view in a longitudinal direction 308 of the thermoelectric generator system 100 in the curved shape 314 as shown in FIG. 8. The thermoelectric generator 102 may be sandwiched between the outer band 316 and the bi-stable spring band 302 and may be capable of flexing from a straight shape 312 shown in FIG. 6 to the curved shape 314 shown in FIG. 9. The thermopile clusters 150 may remain generally rigid and flat while the substrate 158 and heat couple plates 112, 114 may bend and flex along the substrate flex zones 166 and plate flex zones 116.

FIG. 10 is a sectional view in a transverse direction 310 of the thermoelectric generator system 100 in the curved shape 314 as shown in FIG. 8 and showing the substrate 158 and heat couple plates 112, 114 bent along the respective substrate flex zone 166 and plate flex zones 116 to accommodate the slightly convex curvature of the outer band 316 and bi-stable spring band 302 along the transverse direction 310. The sealant 282 may be generally flexible to accommodate the bending of the outer band 316 and bi-stable spring band 302 and may provide mechanical stability to the thermoelectric generator system 100 as indicated above.

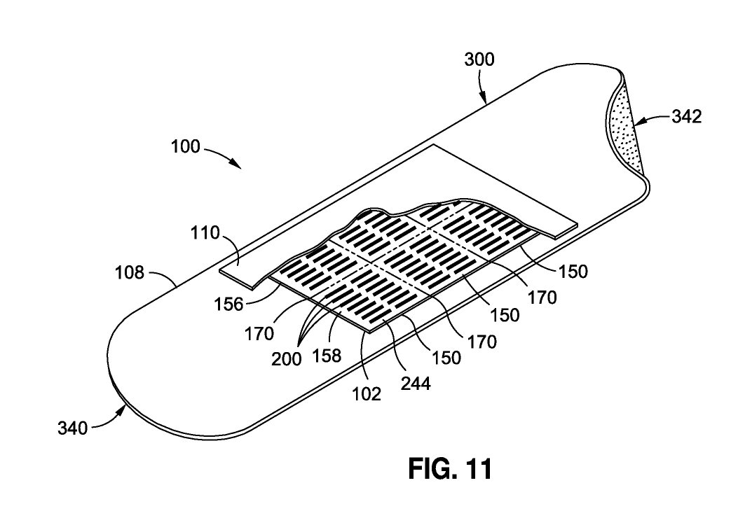

FIG. 11 shows a further embodiment of a band element 300 configuration of the thermoelectric generator system 100 integrated into a flexible adhesive patch 340. The flexible adhesive patch 340 may be resiliently bendable in one or more out-of-plane directions. Furthermore, the flexible adhesive patch 340 may be configured to be either permanently or releasably (e.g., non-permanently) adhesively bonded or applied to a surface. In an embodiment, the adhesive patch 340 may be formed of flexible material such as a woven material or a fabric material. The adhesive patch 340 may be formed of metallic and/or non-metallic material. In some embodiments, the adhesive patch 340 may include pressure-sensitive adhesive 342 on at least a portion of the inner surface 306 of the patch 340 to allow the patch 340 to be adhesively bonded to a surface. For example, the opposing ends of the adhesive patch 340 may include pressure sensitive adhesive to allow the adhesive patch 340 to be applied to the skin surface of a human or animal or to the external surface of a pipe or other heat source 104 or heat sink 106. In an embodiment, the flexible adhesive patch 340 may have electronic components integrated into the patch 340. The flexible adhesive patch 340 with flexible thermoelectric generator 102 may be a free-standing, self-contained, power-generating device that may be conformable to curve surfaces without the need for mechanical fastening devices. In this regard, the flexible adhesive patch 340 may be applied to areas of the body where it is difficult to use mechanical solutions to attach a device.

In any one of the embodiments disclosed herein, the thermoelectric generator system 100 may comprise an integrated flexible thermoelectric generator 102 including a currently-known thermoelectric module in cross-plane configuration sandwiched between the heat collector 108 and the heat exchanger 110. Although the thermoelectric module may be rigid or flexible, the heat collector 108 and the heat exchanger 110 may be non-rigid or flexible. The top and/or bottom heat couple plate 112,114 may preferably be non-rigid but may also be rigid or may be omitted entirely. In addition, although the present disclosure describes the thermoelectric generator system 100 in the context of an energy harvester or power-generating device, the arrangements disclosed herein may be directed towards a heat sensor. It should also be noted that the flexible thermoelectric generator 102 disclosed herein may be provided in configurations other than a planar configuration as disclosed in the above-referenced U.S. application Ser. No. 12/605,370 entitled PLANAR THERMOELECTRIC GENERATOR. For example, the concept of substrate flex zones 166 and heat couple plate flex zones 116, bi-stable spring bands 302, adhesive patches 340, and other features may be implemented in a thermoelectric generate having an in-plane configuration, a cross-plane configuration, a bulk configuration, or any other configuration.

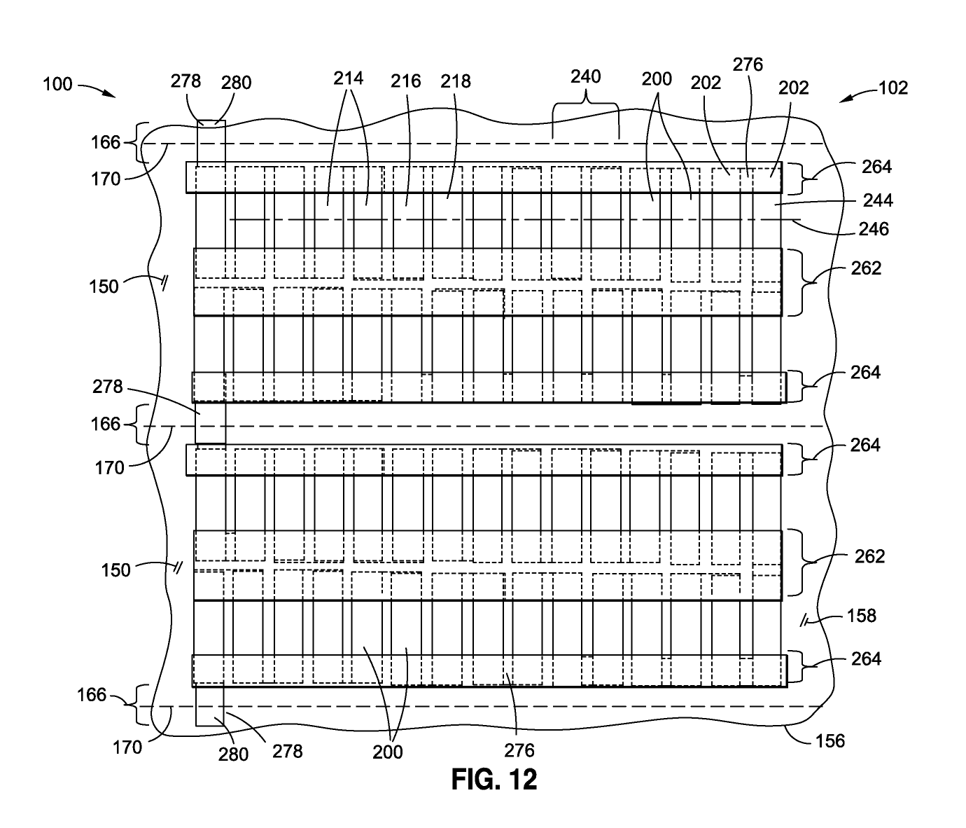

FIG. 12 is a top view of an embodiment of a thermoelectric generator 102 having a substrate flex zone 166 allowing for flexing of the substrate 158 in a single direction. In this regard, the substrate 158 may flex along the horizontal and centrally located substrate flex zone 166 represented by the flex line 170 illustrated in dashed font. The substrate flex zone 166 separates two (2) rigid thermopile clusters 150 each having a pair of rows 244 of thermoelectric legs 200. In addition, each one of the rigid thermopile clusters 150 includes a centrally located dual thermally conductive strip 262 and a pair of single thermally conductive strips 264 on opposite sides of the dual thermally conductive strip 262.

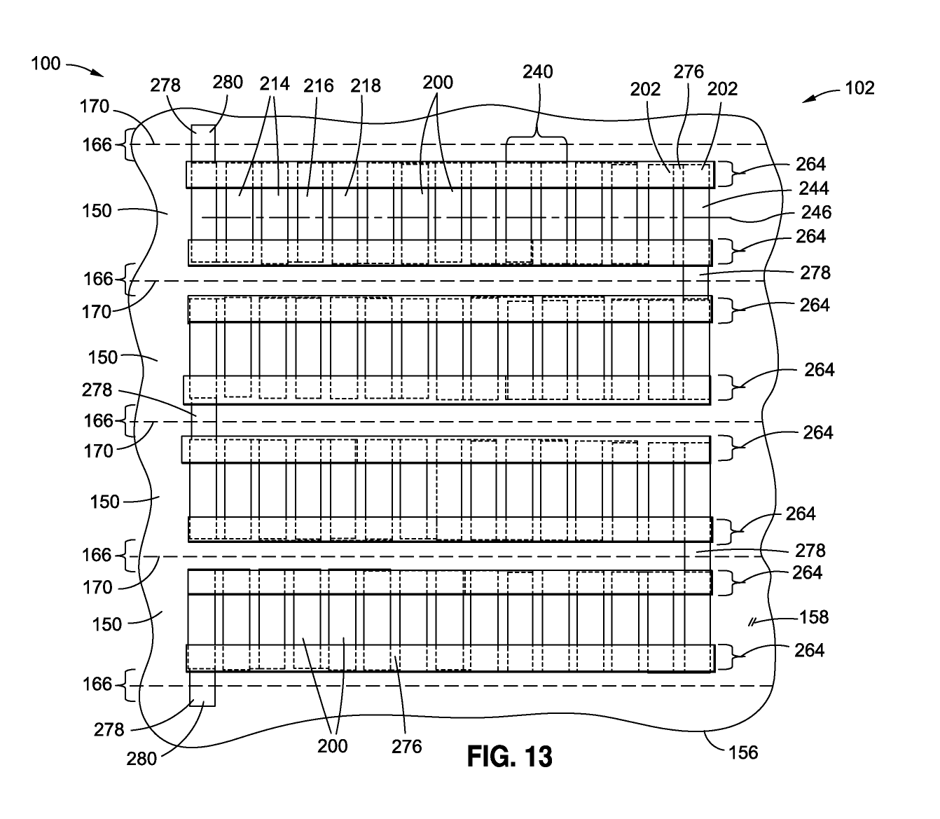

FIG. 13 is a top view of an embodiment of a thermoelectric generator 102 having multiple, parallel substrate flex zones 166 separating four (4) rigid thermopile clusters 150. Each one of the rigid thermopile clusters 150 includes a single row 244 of thermoelectric legs 200. In addition, each one of the rigid thermopile clusters 150 includes a pair of single thermally conductive strips 264 on opposite leg ends 202 of the thermoelectric legs 200 in the row 244.

FIG. 14 is a sectional view of the flexible thermoelectric generator 102 of FIG. 13 showing the plurality of single thermally conductive strips 264. Each one of the single thermally conductive strips 264 may be aligned with opposite leg ends 202 of the thermoelectric legs 200 in each row 244. A top heat couple plate 112 and a bottom heat couple plate 114 may be thermally coupled to opposite leg ends 202 by means of the single thermally conductive strips 264. Advantageously, by limiting the rigid thermopile clusters 150 to a single row 244 of thermoelectric legs 200, the flexible thermoelectric generator 102 may conform to curved surfaces of relatively small radii.

FIG. 15 illustrates an embodiment of a flexible thermoelectric generator 102 wherein the thermoelectric legs 200 in each row 244 form a zig-zag pattern 136. In this regard, the leg axes 204 of adjacent pairs of the thermoelectric legs 200 form an acute angle with one another such that the series of thermoelectric legs 200 in the row 244 form the zig-zag pattern 136. At least one of the alternating legs may be oriented in non-perpendicular relation to the row axis 246. Instead of using metal bridges 276 to interconnect the leg ends 202 as shown in FIGS. 1, 5, 12, and 13, the leg ends 202 in FIG. 15 overlap one another at the junction thereof such that the thermoelectric legs 200 form the zig-zag pattern 136. Heat flow along a lengthwise direction 130 (e.g., see FIG. 2) through the thermoelectric legs 200 results in electricity flowing in a zig-zag pattern 136 through the thermoelectric legs 200 as shown in FIG. 15.

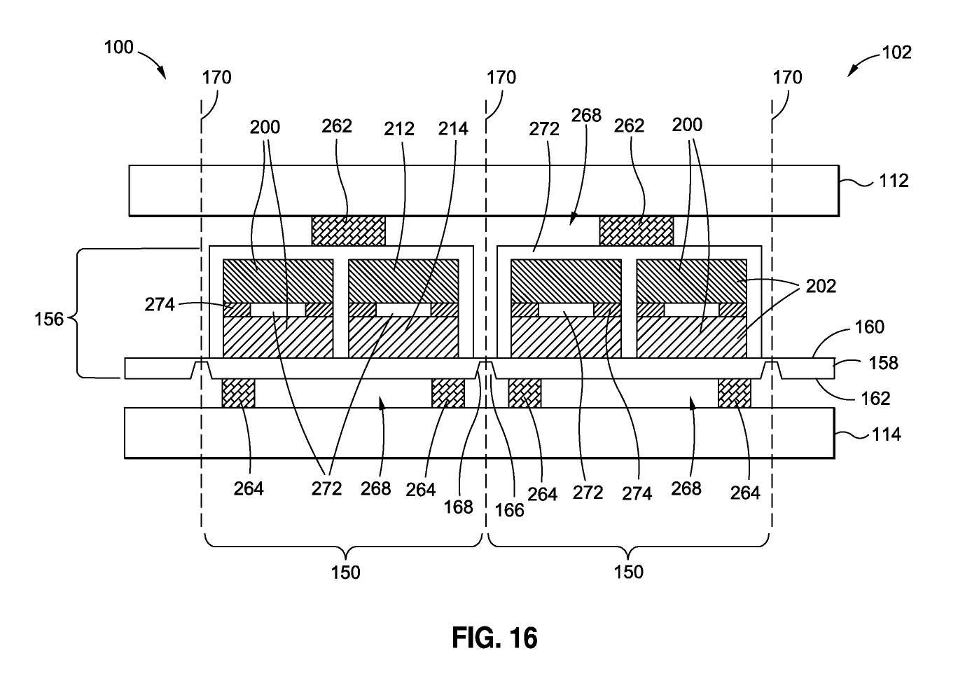

FIG. 16 is a sectional view of the thermoelectric generator 102 of FIG. 15 illustrating an electrically insulating layer 272 interposed between the layers of thermoelectric legs 200. The electrically insulating layer 272 may electrically insulate a substantial length of the semiconductor legs 214 except for at the leg ends 202 where an opening 274 may be formed in the electrically insulating layer 272. The opening 274 in the electrically insulating layer 272 may allow the legs 200 to electrically connect with one another at the leg ends 202. In some examples, metal material may be provided to (e.g., in the openings 274) to electrically connect the dissimilar material thermoelectric legs 200 and/or as a diffusion barrier.

In FIGS. 15-16, the zig-zag pattern 136 may result in an increase in the density of the thermoelectric legs 200 on the substrate 158 relative to the density of thermoelectric legs 200 in a meandering pattern 134 (e.g., FIGS. 1, 5, 12, and 13). The thermoelectric legs 200 in a zig-zag pattern 136 may comprise semiconductor legs 214 (i.e., either n-type thermoelectric legs 216 or p-type thermoelectric legs 218) in alternating arrangement with metal legs 212 which may result in a lower power output relative to the power output for an arrangement of alternating n-type and p-type thermoelectric legs 218. Although the power output of the configuration illustrated in FIG. 15 may be lower, the increased density of thermoelectric legs 200 in the zig-zag pattern 136 may partially compensate for the relatively lower power output. Furthermore, because only one type of semiconductor material is required (e.g., either n-type or p-type), the production costs for the alternating metal legs 212 and semiconductor legs 214 may be reduced. The double layer configuration shown in FIG. 16 may stiffen the cluster and add mechanical stability and improve the compactness of the flexible thermoelectric generator system 100 relative to a single layer configuration (FIG. 2).

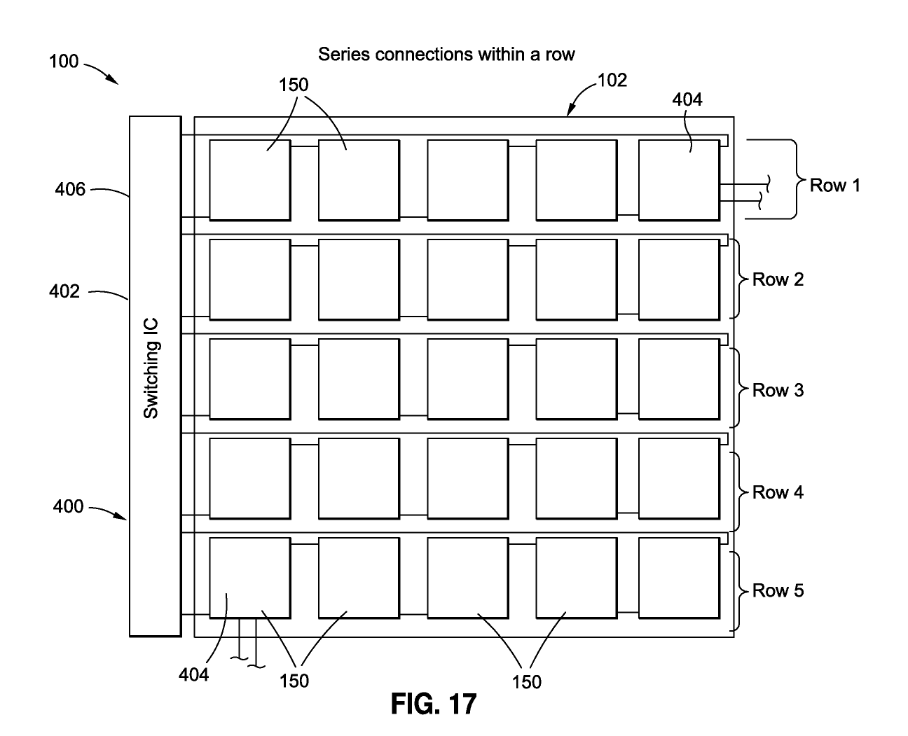

FIG. 17 shows an embodiment of a flexible thermoelectric generator system 100 having a plurality of thermopile clusters 150 electrically connected in series within each row 244 of rigid thermopile clusters 150. Each one of the rows 244 of thermopile clusters 150 may be electrically coupled to power management electronics 400. The power management electronics 400 may include a power matching circuit 402 configured to provide continuous power matching to a load (not shown) powered by the thermoelectric generator system 100. In an embodiment not shown, the power management electronics 400 may determine the open circuit voltage by temporarily disconnecting the load from the thermoelectric generator 102 for a short period of time during which power generation in unavailable. In an embodiment, the power management electronics 400 may include an electronic switch 406 such as a logic controller or switching circuitry. The electronic switch 406 may be coupled to the thermopile clusters 150 and may be configured to change the type of electrical connection between the rows 244 of thermopile clusters 150. For example, in FIG. 17, the electronic switch 406 may be configured to change between series, parallel, or combinations of series and parallel connections between the thermopile clusters 150. In some embodiments, the electronic switch 406 may be operated in a manner such that the thermoelectric generator 102 provides a predetermined voltage range (e.g., power output) independent of the temperature gradient across the thermoelectric generator 102.

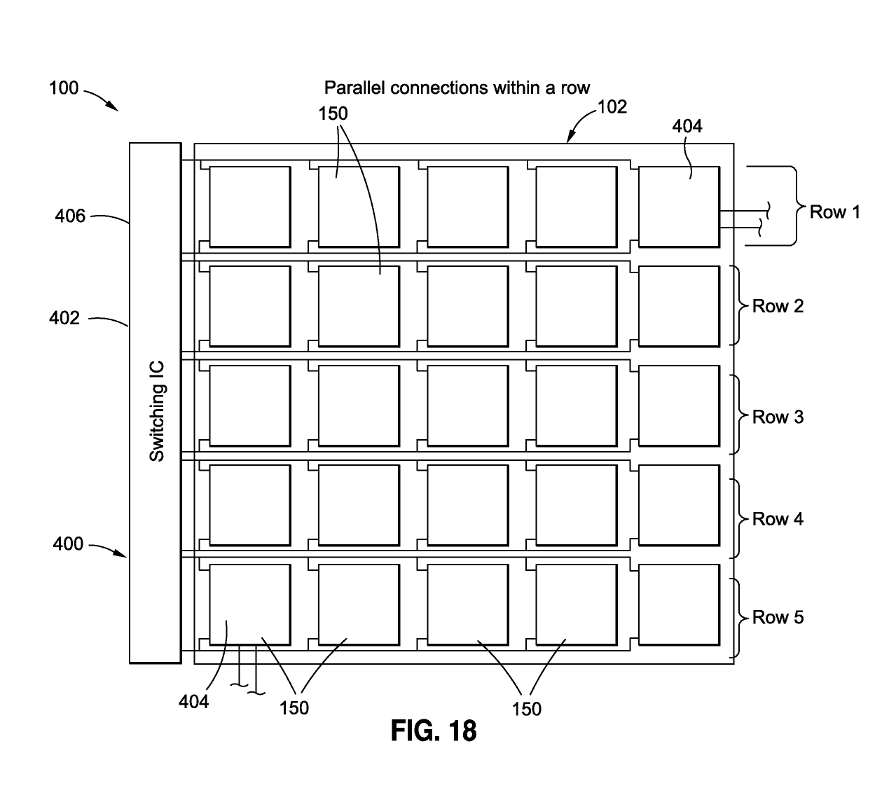

FIG. 18 shows an embodiment of a flexible thermoelectric generator system 100 having a plurality of thermopile clusters 150 electrically connected in parallel within each row. The parallel connection may provide redundancy in the event that one of the thermopile clusters 150 fails. The power management electronics 400 may include the electronic switch 406 coupled to the rows 244 of thermopile clusters 150 and configured to control the manner in which the thermopile clusters 150 are electrically connected. As indicated above, the electronics switch may be configured to change the type of electrical connection between the rows 244 of thermopile clusters 150 based on the voltage requirements of the load.

In another embodiment of a flexible thermoelectric generator system 100 each one of the thermopile clusters 150 is independently connected to the power management electronics 400. Due to the independent connection of each thermal power cluster to the power management electronics 400, the electronic switch 406 may provide a higher level of fidelity in controlling the power output of the thermoelectric generator 102 relative to the arrangements shown in FIGS. 17-18.

In another embodiment not shown the thermoelectric generator system 100 may include more than one power management electronics 400 for independently controlling the thermopile clusters 150 that are connected to an electronic switch 406 that may be included in each one of the power management electronics 400. In any one of the embodiments disclosed herein, the power management electronics 400 may be configured to provide voltage in a relatively narrow range to match the load. For a thermoelectric generator 102 having a given arrangement of thermopiles, the generated thermoelectric voltage is proportional to the temperature difference across the thermopile. In the example of a flexible thermoelectric generator 102 integrated into a bi-stable spring band 302 or wristband as described above, the flexible thermoelectric generator 102 may be subjected to varying temperature differences across the thermopiles due to exposure to different levels of activity and different environments of the person wearing the bi-stable spring band 302 or wristband.

For example, the flexible thermoelectric generator 102 may be subjected to varying body surface temperatures due to changes in metabolism of the wearer, and different heat exchange rates due to changes in body movements of the wearer and/or due to changes in environment such as location (e.g., indoors at room temperature vs. outdoors at a colder or hotter temperature than room temperature). The variation in temperature difference across the thermopiles results in variations in the generated voltage supplied to the load. Advantageously, the power management electronics 400, the power-matching circuit 402, and/or the electronic switch 406 may be configured to autonomously change the connection type of the thermopile clusters 150 between series, parallel, or combinations thereof, to provide a relatively narrow range of voltage to the load independent of the temperature difference across the thermopiles. In this regard, a relatively narrow input voltage range for the power management electronics 400 and optional boost converter may allow for a relatively high overall conversion efficiency of the electronics. The electronic switch 406 may allow for customizing of the voltage requirement for power matching of the thermoelectric generator 102 or sensor output.

In a further embodiment not shown, the thermoelectric generator system 100 may include at least one dedicated temperature gradient-sensing thermocouple or a thermopile cluster 150 that may be electrically coupled to a power-matching circuit 402. The temperature gradient-sensing thermocouple or thermopile cluster may be substantially similar to one of the thermopiles used for power generation, except that the temperature gradient-sensing thermocouple may be electrically separated from the remaining thermopile in a thermopile cluster 150. One or more temperature-gradient-sensing thermopiles may be configured to monitor the temperature gradient across the footprint of the flexible thermoelectric generator 102 so that the electronics which may adjust the type of electrical connection (e.g., series connection and/or parallel connection) between the thermopile clusters 150 to generate voltage within a preferred range for the load.

The power-matching circuit 402 may be configured to intermittently or periodically disconnect the thermoelectric generator 102 from the load and measure the open-circuit voltage so that the electronics which may adjust the type of connection (e.g., series and/or parallel) between the thermopile clusters 150 to generate voltage within a preferred range for the load.

The temperature gradient-sensing thermopile may optionally be configured to function as a heat flow sensor to provide an indication of energy consumption by the load. The voltage output of the thermoelectric generator 102 may provide an indication to the wearer and/or may give the wearer an indication of the quality of fit of the device so that the wearer made adjust the fit of the device. For example, upon receiving an indication of a relatively low output voltage, a wearer of a bi-stable spring band 302 or wristband may adjust the fit of the bi-stable spring band 302 in order to improve the voltage output.

In an embodiment not shown, the thermoelectric generator system 100 may include a foil assembly 156 having a separate thin-film structure (not shown) configured to measure temperature. Such a thin-film structure may be formed of the same materials used for forming the electrical interconnects 278 coupling the thermopile clusters 150 or the metal bridges 276 coupling the thermoelectric legs 200. The thin-film structure may be deposited onto the substrate 158 during the same process step. In an embodiment, the thin-film structure may preferably be formed of metallic material having a relatively high temperature coefficient of the electrical resistance. In an embodiment, the metallic material for forming the thin-film structure may include platinum, nickel, and/or nickel-chromium alloys or any other suitable alloys or combinations thereof. The thin-film structure may also be formed of materials that provide a mechanically and electrically stable thin-film. The temperature-dependent electrical resistance of the thin-film structure may be measured such as by using a bolometer or other suitable measurement device.

In some embodiments, an electrical connector (not shown) may be integrated into the flexible thermoelectric generator 102 application for embodiments where the final electronics (e.g., load) to be powered is not integrated into the flexible thermoelectric generator system 100. In such an arrangement, the flexible thermoelectric generator 102 may cooperate with the integrated power management electronics 400 to provide a regulated power source. In this regard, the final electronic device (e.g., the load) may be plugged into the thermoelectric generator system 100 for powering the electronic device and/or for charging the electronic device.

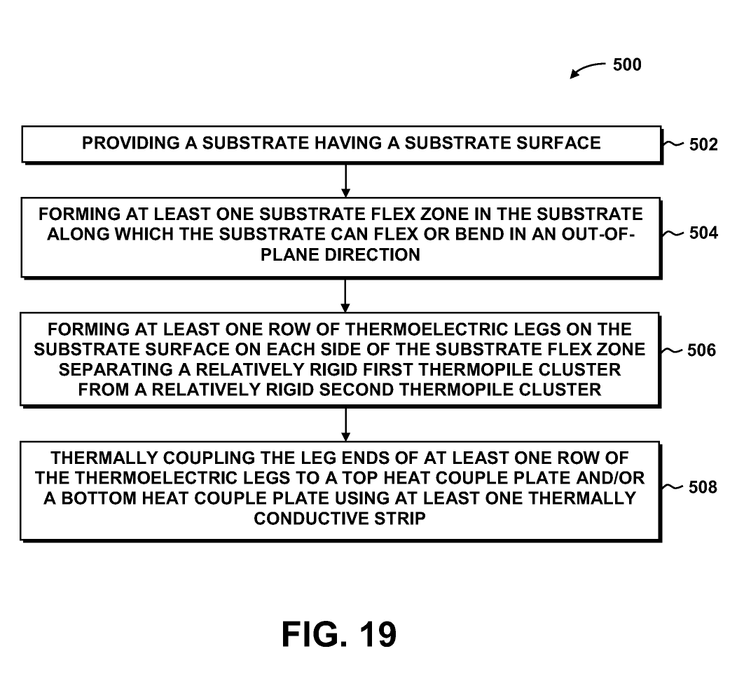

Referring to FIG. 19, shown is a flowchart illustrating one or more operations that may be included in a method 500 of forming a thermoelectric generator system 100. Step 502 of the method 500 may include providing a substrate 158 having a substrate surface. As shown in FIG. 2, the substrate 158 may include an upper substrate surface 160 and a lower substrate surface 162 and may be formed of an electrically insulating material having a relatively low thermal conductivity such as polyimide material (e.g., Kapton®). In an embodiment, the substrate 158 may be provided in a length and width that may support the total quantity of thermoelectric legs 200 to be formed on the substrate 158. In some examples, the method may include forming thermoelectric legs 200 on a sheet (not shown) of substrate. The sheet of substrate may be later subdivided for use in assembling multiple thermoelectric generators 102.

Step 504 of the method 500 may include forming at least one substrate flex zone 166 in the substrate 158 along which the substrate 158 can flex or bend in an out-of-plane direction while the remaining portions of the substrate 158 (e.g., the thermopile clusters 150) may be substantially rigid or non-flexible. As indicated above, the substrate flex zone 166 may comprise a relatively narrow region of the substrate 158 as shown in FIG. 1. The process of forming the substrate flex zone 166 may include locally reducing the substrate thickness 164 in at least a portion of the substrate flex zone 166 relative to the substrate thickness 164 in a thermopile cluster 150. In some examples, the substrate 158 may be thinned by etching the substrate 158, mechanically cutting notches or grooves in the substrate surface(s), and/or laser treating the substrate 158 to locally thin the substrate 158 and/or to form holes, slots, grooves, and/or notches in the substrate 158. The substrate flex zone 166 may also be formed by omitting the electrically insulative coating (e.g., see FIG. 2) on the substrate 158 in the area of the substrate flex zone 166. The step of forming the substrate flex zone 166 may include forming at least one substrate flex zone 166 generally parallel to a row axis 246 or generally perpendicular to the row axis 246 as shown in FIG. 1. In some examples, the method may include forming at least two of the substrate flex zones 166 in non-parallel (e.g., substantially perpendicular) relation to one another to allow the substrate 158 to flex in two different out-of-plane directions.

Step 506 of the method 500 may include forming at least one row 244 of thermoelectric legs 200 on the upper substrate surface 160 and/or the lower substrate surface 162. Rows 244 of thermoelectric legs 200 may be formed on each side of the substrate flex zone 166. As shown in FIG. 1, the substrate flex zones 166 separate the relatively rigid thermopile cluster 150 from one another. Each thermopile cluster 150 may include at least one row 244 of thermoelectric legs 200. As indicated above, each row 244 of thermoelectric legs 200 may be comprised of alternating materials (e.g., alternating dissimilar semiconductor materials, or alternating semiconductor material and metallic material). The alternating semiconductor materials may comprise alternating n-type and p-type semiconductor material.

The method may include forming the thermoelectric legs 200 such that the leg axes 204 are oriented substantially perpendicular to the row axis 246 such that the series of thermoelectric legs 200 in a row 244 forms a meandering pattern 134. The thermoelectric legs 200 may be electrically connected in series by coupling the leg ends 202 using metal bridges 276 as shown in FIG. 1. Alternatively, the method may include forming the thermoelectric legs 200 such that the leg axes 204 are oriented at an acute angle as shown in FIG. 15 such that the series of thermoelectric legs 200 form a zig-zag pattern 136. As indicated above, for a zig-zag pattern 136, the leg ends 202 may overlap and may be electrically coupled by providing a hole in the electrically insulating layer 272 that electrically insulates adjacent legs 200. Thermopile clusters 150 may be electrically coupled by forming an electrical interconnect 278 on the substrate 158 and extending the electrical interconnect 278 across the substrate flex zone 166. Optionally, the thermopile clusters 150 may be electrically coupled using an electrically conductive adhesive in addition to the electrical interconnects 278 or as an alternative to the electrical interconnects 278, as described above. The electrically conductive adhesive may be flexible to allow for the flexibility of the flex zones 166 and thereby improve the reliability of the electrical interconnect between thermopile clusters 150.

Step 508 of the method 500 may additionally include thermally coupling the leg ends 202 of at least one row 244 of the thermoelectric legs 200 to a top heat couple plate 112 and/or to a bottom heat couple plate 114 in a manner to form thermal gaps 268 as shown in FIG. 2. The thermal gaps 268 may optionally be filled with the thermally insulating material to improve the temperature differential across the length of the thermoelectric legs 200. The method may additionally include providing a top heat couple plate 112 and/or a bottom heat couple plate 114 for heat transfer (e.g., heat input, heat rejection) to or from a heat source 104 (e.g., human or animal body surface, warm pipe in a factory, etc.) and a heat sink 106 (e.g., ambient air, other). Flexibility of the thermoelectric generator 102 may be enhanced by providing the top heat couple plate 112 and/or the bottom heat couple plate 114 with one or more plate flex zones 116. In an embodiment, the plate flex zones 116 may be substantially aligned with the substrate flex zones 166 to facilitate flexing or bending of the thermoelectric generator 102. However, in a further embodiment not shown, the heat couple plates 112, 114 may be provided as physically separate heat couple plate segments dedicated to a thermopile cluster 150. Such heat couple plate segments may be physically separate but may come into physical contact with one another as the thermoelectric generator 102 is flexed or bent.

The method may additionally include providing thermally conductive strip 260 on a side of the substrate 158 defined by the upper substrate surface 160 and/or on a side of substrate 158 defined by the lower substrate surface 162. Thermally conductive strips 260 may be generally aligned with the row axis 246 and positioned over and thermally coupled to the leg ends 202 of the thermoelectric legs 200. Each thermally conductive strip 260 may thermally couple the leg ends 202 of the thermoelectric legs 200 to a nearest one of the top heat couple plate 112 and bottom heat couple plate 114 such that heat flows in a lengthwise direction 130 through the thermoelectric legs 200 as shown in FIG. 2. The heat flow may cause electricity to flow in a meandering pattern 134 (FIG. 1) or a zig-zag pattern 136 (FIG. 15) through the thermoelectric legs 200. In some embodiments, the method may include providing at least two rows 244 of thermoelectric legs 200 in a first thermopile cluster 150 and/or in a second thermopile cluster 150 wherein the rows 244 may be generally parallel to one another. The method may additionally include providing at least one of the thermally conductive strips 260 as a single thermally conductive strip 264 for thermally coupling the top heat couple plate 112 to the leg ends 202 of the thermoelectric legs 200 in a single one of the rows 244, or thermally coupling the bottom heat couple plate 114 to the leg ends 202 of the thermoelectric legs 200 in a single one of the rows 244 (FIG. 2).

In a further embodiment, the method may include forming at least two rows 244 of thermoelectric legs 200 in a first thermopile cluster 150 and/or in a second thermopile cluster, and providing at least one of the thermally conductive strips 260 as a dual thermally conductive strip 262 for thermally coupling the top heat couple plate 112 (FIG. 2) and/or bottom heat couple plate 114 to the leg ends 202 of the thermoelectric legs 200 in two rows 244 of thermoelectric legs 200. In some embodiments, the method may include positioning a pair of thermally conductive strips 260 respectively on opposite sides of the substrate 158 as defined by the upper substrate surface 160 and the lower substrate surface 162. The pair of thermally conductive strips 260 may be respectively aligned with and may thermally couple opposite leg ends 202 of the thermoelectric legs 200 to the respective top and bottom heat couple plate 112, 114 for each row 244 of thermoelectric legs 200 in each one of the first and second thermopile clusters 150.

The method may additionally include providing means for managing the power output of the thermoelectric generator 102. For example, the method may include electrically coupling a power-matching circuit 402 to a dedicated temperature gradient-sensing thermopile 404 that may be electrically separate from the remaining thermopiles 404 in a thermopile cluster 150. As described above, such a temperature gradient-sensing thermopile 404 may be configured to monitor the temperature gradient across the thermoelectric generator 102. Alternatively, a power-matching circuit 402 may be configured to periodically disconnect the thermoelectric generator 102 from the load, and measure the open-circuit voltage, and then configure the electrical connection of the thermopile clusters 150 such that an appropriate voltage range may be provided to the load.

The method may further include the step of coupling the thermopile clusters 150 to an electronic switch 406 such as a logic controller or switching circuitry of the power management electronics 400. As indicated above, the electronic switch 406 may be configured to change the type of electrical connection connecting the thermopile cluster 150 between series, parallel, or combinations thereof, and vary the voltage generated by the thermopile clusters 150. In this manner, the electronic switch 406 may provide a desired voltage range regardless of the temperature gradient that may exist across the thermoelectric generator 102.

In an embodiment not shown, each thermopile cluster 150 may be sealed around the perimeter, and may include electrical wiring extending through the top heat couple plate and/or bottom heat couple plate through vias formed in the top and/or bottom heat couple plate.

In a further embodiment not shown, a thermoelectric generator may be configured as one or more rigid disc clusters. Each rigid disc cluster may have the shape of a disc with legs arranged in circular rows. A thermally conductive dot (not shown) on one side of the substrate side may thermally connect the legs to a top heat couple plate. A concentric ring-shaped thermally conductive strip may be thermally coupled to the legs to a bottom heat couple plate on an opposite side of the substrate. Multiple discuss may be arrange in the same plane to minimize the area of the substrate between the rigid disc clusters which may be bordered by curved flex lines arrange the discs. A radial arrangement of rigid disc clusters may be electrically interconnected to a flexible printed circuit using glue or solder.

Additional modifications and improvements of the present disclosure may be apparent to those of ordinary skill in the art. Thus, the particular combination of parts described and illustrated herein is intended to represent only certain embodiments of the present disclosure and is not intended to serve as limitations of alternative embodiments or devices within the spirit and scope of the disclosure.

What is claimed is:

1. A thermoelectric generator system, comprising:
a flexible thermoelectric generator, including:
a substrate formed of an electrically insulating material having a relatively low thermal conductivity;
a series of thermoelectric legs formed of alternating dissimilar materials arranged in at least two rows on the substrate, each one of the thermoelectric legs defining a leg axis extending along a lengthwise direction of the thermoelectric leg, the axes being generally parallel to a substrate surface and non-parallel to a row axis; and
the substrate including at least one substrate flex zone located between two of the rows of thermoelectric legs, the substrate flex zone defining a relatively rigid first thermopile cluster and a relatively rigid second thermopile cluster, the substrate having greater flexibility in the substrate flex zone relative to the flexibility of the substrate in the first thermopile cluster and the second thermopile cluster.

2. The thermoelectric generator system of claim 1, wherein:
the substrate flex zone comprises a region of localized thinning of the substrate.

3. The thermoelectric generator system of claim 1, wherein:
the substrate includes at least two of the substrate flex zones being non-parallel to one another; and
the substrate flex zones allowing the substrate to flex in two different out-of-plane directions.

4. The thermoelectric generator system of claim 1, wherein:
the leg axes of the thermoelectric legs in at least one row are oriented in substantially perpendicular relation to the row axis such that the series of thermoelectric legs in the row form a meandering pattern.

5. The thermoelectric generator system of claim 1 wherein:
the leg axes of adjacent pairs of the thermoelectric legs forming an acute angle such that the series of thermoelectric legs in the row form a zig-zag pattern.

6. The thermoelectric generator system of claim 1, further comprising:
a top heat couple plate and/or a bottom heat couple plate thermally coupled to the thermoelectric legs.

7. The thermoelectric generator system of claim 6, wherein:
at least one of the top and bottom heat couple plate has a plate flex zone substantially aligned with the substrate flex zone.

8. The thermoelectric generator system of claim 1, wherein:
the first thermopile cluster and/or the second thermopile cluster includes at least one thermally conductive strip located on at least one surface of the substrate, the thermally conductive strip being aligned with leg ends of the thermoelectric legs such the leg ends are thermally coupled to a heat couple plate.

9. The thermoelectric generator system of claim 8, wherein:
the thermally conductive strip is configured as a single thermally conductive strip thermally coupling a heat couple plate to leg ends of single row of the thermoelectric legs.

10. The thermoelectric generator system of claim 8, wherein:
the thermally conductive strip is configured as a dual thermally conductive strip thermally coupling a heat couple plate to leg ends of two rows of the thermoelectric legs.

11. The thermoelectric generator system of claim 1, wherein:
the flexible thermoelectric generator is integrated into a flexible bi-stable spring band that is substantially straight and stable when the bi-stable spring band is in a straight shape and being curved and stable when the bi-stable spring band is in a curved shape; and
the bi-stable spring band having an outer surface that is concave in a transverse direction when the bi-stable spring band is in the straight shape and the outer surface being convex in the transverse direction when the bi-stable spring band is in the curved shape.

12. The thermoelectric generator system of claim 1, wherein:
the flexible thermoelectric generator is integrated into a flexible adhesive patch configured to be releasably adhesively attached to an external surface.

13. The thermoelectric generator system of claim 1, further comprising:
an electronic switch coupled to the thermopile clusters and configured to change a type of electrical connection between the thermopile clusters including a series connection, a parallel connection, and combinations thereof; and
the electronic switch operating in a manner such that the thermoelectric generator provides a predetermined voltage independent of a temperature gradient across the thermoelectric generator.

14. A thermoelectric generator system, comprising:
a flexible band element;
a flexible thermoelectric generator mounted to the flexible band element, the flexible thermoelectric generator including:
a substrate formed of an electrically insulating material having a relatively low thermal conductivity;
a series of thermoelectric legs formed of alternating dissimilar materials arranged in at least two rows on the substrate, each one of the thermoelectric legs defining a leg axis extending along a lengthwise direction of the thermoelectric leg, the axes being generally parallel to a substrate surface and non-parallel to a row axis; and
the substrate including at least one substrate flex zone located between two of the rows of thermoelectric legs, the substrate flex zone defining a relatively rigid first thermopile cluster and a relatively rigid second thermopile cluster, the substrate having greater flexibility in the substrate flex zone relative to the flexibility of the substrate in the first thermopile cluster and the second thermopile cluster.

15. The thermoelectric generator system of claim 14, wherein the flexible band element comprises:
a flexible bi-stable spring band that is substantially straight and stable when the bi-stable spring band is in a straight shape and being curved and stable when the bi-stable spring band is in a curved shape; and
the bi-stable spring band having an outer surface that is concave in a transverse direction when the bi-stable spring band is in the straight shape and the outer surface being convex in the transverse direction when the bi-stable spring band is in the curved shape.

16. The thermoelectric generator system of claim 15, wherein the flexible band element comprises:
a flexible adhesive patch configured to be releasably adhesively attached to an external surface.

17. A method of forming a thermoelectric generator system, comprising the steps of:
providing a substrate having a substrate surface and formed of an electrically insulating material having a relatively low thermal conductivity;
forming in the substrate at least one substrate flex zone along which the substrate can bend in an out-of-plane direction;
forming on each side of the substrate flex zone at least one row of thermoelectric legs on the substrate surface, the substrate flex zone separating a relatively rigid first thermopile cluster and a relatively rigid second thermopile cluster, each thermopile cluster including at least one row of the thermoelectric legs formed of alternating dissimilar materials and electrically connected in series, the substrate having greater flexibility in the substrate flex zone relative to the flexibility of the substrate in the first thermopile cluster and the second thermopile cluster; and
each one of the thermoelectric legs defining a leg axis extending along a lengthwise direction of the thermoelectric leg, the leg axis being generally parallel to the substrate surface and non-parallel to a row axis.

18. The method of claim 17, wherein the step of forming the substrate flex zone comprises:
reducing a substrate thickness in the substrate flex zone relative to the substrate thickness in at least one of the first thermopile cluster and the second thermopile cluster.

19. The method of claim 17, wherein the step of forming the substrate flex zone comprises:
orienting the substrate flex zone generally parallel to a row axis or generally perpendicular to a row axis.

20. The method of claim 17, wherein the step of forming the substrate flex zone comprises:
forming at least two of the substrate flex zones in non-parallel relation to one another in a manner allowing the substrate to flex in two different out-of-plane directions.

21. The method of claim 17, further comprising:
providing a thermally conductive strip on at least one side of the substrate and aligned with leg ends of the thermoelectric legs in at least one row of at least one of the first and second thermopile clusters, the thermally conductive strip thermally coupling the leg ends to a heat couple plate.

22. The method of claim 21, further comprising:
providing a plate flex zone in at least one of a top heat couple plate and a bottom heat couple plate; and
substantially aligning the plate flex zone with the substrate flex zone.

23. The method of claim 17, wherein the step of forming the thermoelectric legs and providing at least one thermally conductive strip comprises:
forming at least two rows of thermoelectric legs in the first thermopile cluster and/or the second thermopile cluster; and
providing at least one of the thermally conductive strips as a single thermally conductive strip thermally coupling a heat couple plate to leg ends of the thermoelectric legs in a single one of the rows.

24. The method of claim 17, wherein the step of forming the thermoelectric legs and providing at least one thermally conductive strip comprises:
forming at least two rows of thermoelectric legs in the first thermopile cluster and/or the second thermopile cluster, the rows being generally parallel to one another; and
providing at least one of the thermally conductive strips as a dual thermally conductive strip thermally coupling a heat couple plate to leg ends of the thermoelectric legs in two of the rows of thermoelectric legs.

25. The method of claim 17, further comprising:
extending an electrical interconnect across the substrate flex zone to electrically connect the thermoelectric legs in the first thermopile cluster to the thermoelectric legs in the second thermopile cluster.

26. The method of claim 17, further comprising:
coupling the first and second thermopile cluster to an electronic switch;
changing, using the electronic switch, a type of connection between the first and second thermopile cluster; and
varying a voltage of the first and second thermopile cluster in response to changing the type of connection between the first and second thermopile cluster.
